(19) United States
(12) Patent Application Publication
(10) Pub. No.: US 2026/0025977 A1
(43) Pub. Date: Jan. 22, 2026

(54) SEMICONDUCTOR DEVICES HAVING ACTIVE PATTERNS

(71) Applicant: Samsung Electronics Co., Ltd., Suwon-si (KR)

(72) Inventors: Hyunjin LEE, Suwon-si (KR); Heejae CHAE, Suwon-si (KR); Yongkwan KIM, Suwon-si (KR); Huijung KIM, Suwon-si (KR); Jaehyun CHOI, Suwon-si (KR)

(73) Assignee: Samsung Electronics Co., Ltd., Suwon-si (KR)

(21) Appl. No.: 19/262,224

(22) Filed: Jul. 8, 2025

(30) Foreign Application Priority Data
Jul. 18, 2024 (KR) 10-2024-0095017

(51) Int. Cl. H10B 12/00

(52) U.S. Cl. CPC H10B 12/315; H10B 12/05

(57) ABSTRACT

A semiconductor device includes a bitline structure, a first gate structure extending in a first horizontal direction on the bitline structure and including a first gate electrode, a second gate structure extending in the first horizontal direction on the bitline structure and including a second gate electrode, an active pattern including a portion being between the first gate structure and the second gate structure, and a contact pattern on the active pattern, wherein the active pattern is in contact with an upper surface of the bitline structure and in contact with side surfaces and a lower surface of the first gate structure.

### CROSS-REFERENCE TO RELATED APPLICATION(S)

This application claims benefit of priority to Korean Patent Application No. 10-2024-0095017 filed on Jul. 18, 2024 in the Korean Intellectual Property Office, the disclosure of which is incorporated herein by reference in its entirety.

### BACKGROUND

Example embodiments of the present disclosure relate to semiconductor devices having active patterns.

As demand for higher performance, higher speed, and/or multifunctionality of a semiconductor device increases, integration density of a semiconductor device is increasing. In manufacturing a semiconductor device having fine patterns corresponding to the trend toward higher integration density of a semiconductor device, it may be desired to implement patterns having a fine width or a fine spacing distance.

### SUMMARY

An example embodiment of the present disclosure is to provide semiconductor devices having an active pattern surrounding a first gate structure and connected to two contact patterns.

According to an example embodiment of the present disclosure, a semiconductor device includes a bitline structure, a first gate structure extending in a first horizontal direction on the bitline structure, the first gate structure including a first gate electrode, a second gate structure extending in the first horizontal direction on the bitline structure, the second gate structure including a second gate electrode, an active pattern including a portion being between the first gate structure and the second gate structure, and a contact pattern on the active pattern, wherein the active pattern is in contact with an upper surface of the bitline structure and in contact with side surfaces and a lower surface of the first gate structure.

According to an example embodiment of the present disclosure, a semiconductor device includes a bitline structure, a first gate structure extending in a first horizontal direction on the bitline structure, the first gate structure including a first gate electrode, a second gate structure extending in the first horizontal direction on the bitline structure, each of the second gate structures including a second gate electrode, the second gate structures being apart from each other in a second horizontal direction intersecting the first horizontal direction with the first gate structure interposed therebetween, an active pattern including a portion between the first gate structure and the second gate structures, and a first contact pattern and a second contact pattern on the active pattern, wherein the active pattern is electrically connected to the first contact pattern and the second contact pattern.

According to an example embodiment of the present disclosure, a semiconductor device includes a bitline structure, a first gate structure extending in a first horizontal direction on the bitline structure, the first gate structure including a first gate electrode and a first gate dielectric layer, the first gate dielectric layer being in contact with a side surface and a lower surface of the first gate electrode, a second gate structure extending in the first horizontal direction on the bitline structure, the second gate structure including a second gate electrode and a second gate dielectric layer, the second gate dielectric layer in contact with a side surface of the second gate electrode, an active pattern including a portion being between the first gate structure and the second gate structure, a contact pattern on the active pattern, and a data storage structure on the contact pattern, wherein the active pattern is in contact with an upper surface of the bitline structure, and in contact with side surfaces and a lower surface of the first gate structure, and wherein a lower end of the first gate dielectric layer is apart from the bitline structure in a vertical direction and is at a level higher than a level of a lower surface of the second gate dielectric layer.

### BRIEF DESCRIPTION OF DRAWINGS

The above and other aspects, features, and advantages of the present disclosure will be more clearly understood from the following detailed description, taken in combination with the accompanying drawings, in which:

FIG. 1A is a plan diagram illustrating a semiconductor device according to an example embodiment of the present disclosure;

FIG. 1B is vertical cross-sectional diagrams illustrating a semiconductor device illustrated in FIG. 1A taken along lines I-I′ and II-II′;

FIG. 2 is an enlarged diagram illustrating the semiconductor device illustrated in FIG. 1B;

FIGS. 3 to 10C are plan diagrams illustrating semiconductor devices according to some example embodiments of the present disclosure;

FIG. 11A is a plan diagram illustrating a semiconductor device according to an example embodiment of the present disclosure;

FIG. 11B is vertical cross-sectional diagrams illustrating the semiconductor device illustrated in FIG. 11A taken along lines I-I′ and II-II′;

FIGS. 12 and 13 are plan diagrams illustrating a semiconductor device according to some example embodiments of the present disclosure;

FIGS. 14A to 28 are plan diagrams and vertical cross-sectional diagrams illustrating processes of a method of manufacturing a semiconductor device in order according to an example embodiment of the present disclosure; and

FIG. 29 is a cross-sectional diagram illustrating a layout structure of a back gate electrode and a wordline included in a semiconductor device according to an example embodiment of the present disclosure.

### DETAILED DESCRIPTION

Hereinafter, some example embodiments of the present disclosure will be described as follows with reference to the accompanying drawings.

When the term “about,” “substantially” or “approximately” is used in this specification in connection with a numerical value, it is intended that the associated numerical value includes a manufacturing or operational tolerance (e.g., +10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

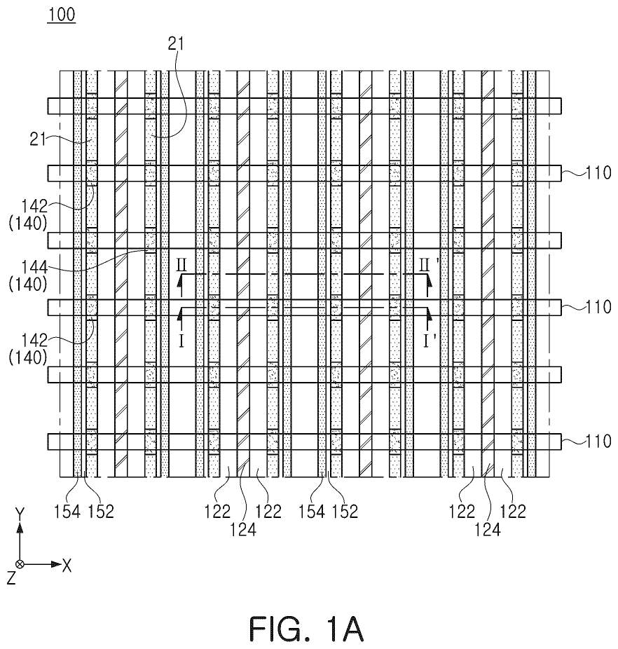

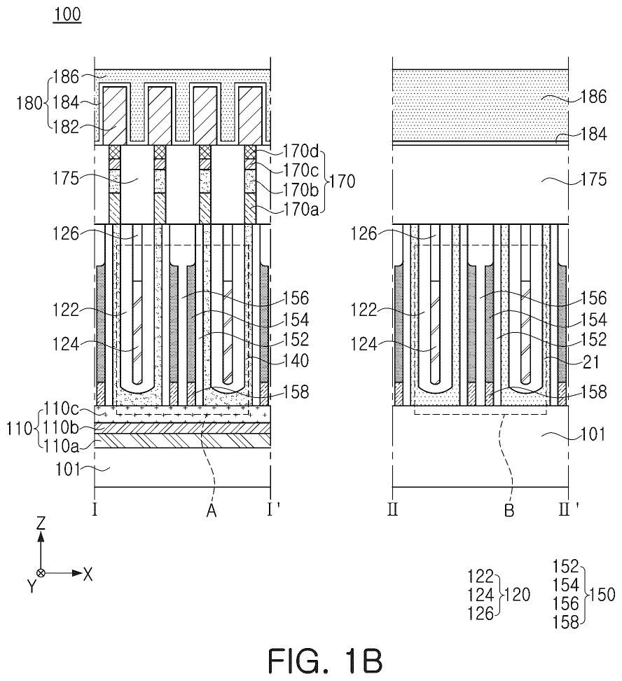

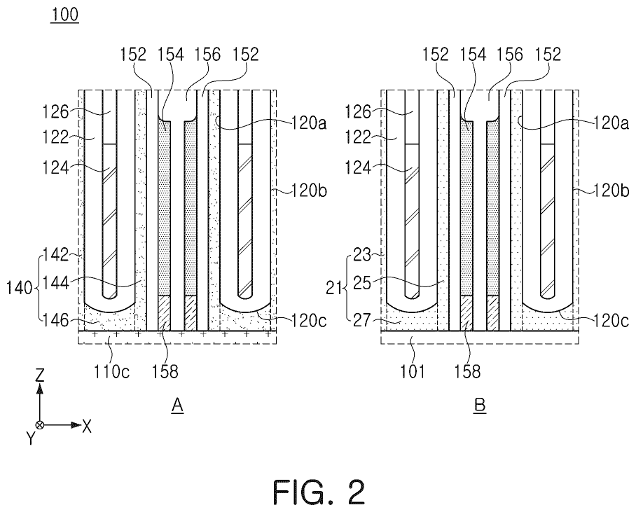

FIG. 1A is a plan diagram illustrating a semiconductor device according to an example embodiment. FIG. 1B is vertical cross-sectional diagrams illustrating a semiconductor device illustrated in FIG. 1A taken along lines I-I′ and II-II′. FIG. 2 is an enlarged diagram illustrating the semiconductor device illustrated in FIG. 1B, corresponding to region A and region B in FIG. 1B.

Referring to FIG. 1A to FIG. 2, a semiconductor device 100 according to an example embodiment may include a lower insulating layer 101, a bitline structure 110, a back gate structure 120, an active pattern 140, a wordline structure 150, a contact pattern 170, and a data storage structure 180.

The semiconductor device 100 may include a vertical channel transistor including an active pattern 140, a bitline structure 110 electrically connected to the active pattern 140, and wordlines 154 disposed on at least one side surface of the active pattern 140.

The semiconductor device 100 may be applied to, for example, a cell array of a dynamic random access memory (DRAM), but example embodiments are not limited thereto.

The lower insulating layer 101 may include an insulating material, such as silicon oxide, silicon nitride, silicon oxynitride (SiON), or silicon carbon nitride (SiCN).

The bitline structure 110 may extend in the X-direction on the lower insulating layer 101. In an example embodiment, the bitline structure 110 may be buried in the lower insulating layer 101. The bitline structure 110 may be electrically connected to the active pattern 140. A plurality of the bitline structure 110 may be provided, and the plurality of bitline structures 110 may be spaced apart from each other in the Y-direction and may extend in parallel to each other.

The bitline structure 110 may include doped polysilicon, metal, conductive metal nitride, metal-semiconductor compound, conductive metal oxide, conductive graphene, carbon nanotube, or a combination thereof. For example, at least one of the bitline structures 110 may be formed of or include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotubes or combinations thereof. In an example embodiment, the bitline structure 110 may include a first conductive pattern 110a, a second conductive pattern 110b and a third conductive pattern 110c stacked in order on the lower insulating layer 101. The first conductive pattern 110a may include a metal material, such as titanium (Ti), tantalum (Ta), tungsten (W), and aluminum (Al), the second conductive pattern 110b may include metal nitride, such as titanium nitride (TiN), or a silicide material, such as titanium silicide (TiSi), and the third conductive pattern 110c may include a semiconductor material, such as polycrystalline silicon. The third conductive pattern 110c may be a layer doped with impurities. However, in example embodiments, the material of the layers included in the bitline structures 110, the number of the layers, and thicknesses thereof may be varied.

In an example embodiment, the semiconductor device 100 may further include shield patterns disposed in the lower insulating layer 101, extending in the X-direction and spaced apart from each other in the Y-direction. For example, the shield patterns may be alternately disposed with the bitline structures 110 in the Y-direction. A lower surface of the shield pattern may be positioned at a level higher than a level of a lower surface of the lower insulating layer 101, and an upper surface of the shield pattern may be positioned at a level lower than a level of an upper surface of the bitline structures 110. The shield patterns may reduce capacitance between the bitline structures 110.

The shield pattern may include doped polysilicon, metal, conductive metal nitride, metal-semiconductor compound, metal compound, conductive metal oxide, graphene, carbon nanotube, or a combination thereof.

The back gate structures 120 may intersect the bitline structures 110. For example, the back gate structures 120 may extend in the Y-direction and may be spaced apart from each other in the X-direction.

The back gate structure 120 may include a back gate dielectric layer 122, a back gate electrode 124, and an upper capping layer 126. The back gate electrodes 124 may extend in the Y-direction and may be spaced apart from each other in the X-direction. The back gate electrode 124 may be configured to remove charges trapped in the active pattern 140. The active pattern 140 may be configured as a floating body, and the back gate electrode 124 may be a structure for supplementing the floating active pattern 140 to prevent or reduce performance degradation of the semiconductor device 100 due to the floating body effect of the active pattern 140.

The back gate electrode 124 may include doped polysilicon, metal, conductive metal nitride, metal-semiconductor compound, conductive metal oxide, graphene, carbon nanotube, or a combination thereof. For example, the back gate electrode 124 may be formed of or include doped polysilicon, Al, Cu, Ti, Ta, Ru, W, Mo, Pt, Ni, Co, TiN, TaN, WN, NbN, TiAl, TiAlN, TiAlC, TaAlC, TiSi, TiSiN, TaSi, TaSlN, RuTiN, NiSi, CoSi, IrOx, RuOx, graphene, carbon nanotubes or a combination thereof, but example embodiments are not limited thereto. The back gate electrode 124 may be formed in a single layer or multiple layers of the materials described above.

The back gate dielectric layers 122 may extend along both side surfaces of the back gate electrodes 124 in the Y-direction. The back gate dielectric layers 122 may cover both side surfaces and a lower surface of the back gate electrodes 124. A vertical length of the back gate dielectric layer 122 may be greater than a vertical length of the back gate electrode 124. For example, an upper surface of the back gate dielectric layer 122 may be positioned at a level higher than a level of an upper surface of the back gate electrode 124, and a lower end of the back gate dielectric layer 122 may be positioned at a level lower than a level of a lower surface of the back gate electrode 124. In an example embodiment, the lower end of the back gate dielectric layer 122 may be spaced apart from the third conductive pattern 110c. A vertical length in the Z-direction of the back gate structure 120 may be less than a vertical length of the wordline structure 150. For example, the upper surface of the back gate structure 120 may be coplanar with the upper surface of the wordline structure 150, and a lower end of the back gate structure 120 may be disposed at a level higher than a level of the lower end of the wordline structure 150. Each of the back gate dielectric layers 122 may include at least one of silicon oxide or a high-κ dielectric.

The upper capping layer 126 may be disposed on the back gate electrode 124. Side surfaces of the upper capping layer 126 may be in contact with the back gate dielectric layer 122, and an upper surface of the upper capping layer 126 may be coplanar with upper surfaces of the back gate dielectric layers 122. The upper capping layer 126 may include silicon oxide, silicon nitride, silicon oxynitride, silicon carbonitride, low-K dielectric, or a combination thereof.

The active pattern 140 may be disposed on the bitline structure 110, and may extend in the vertical direction (Z-direction). The active patterns 140 may be spaced apart from each other in the X-direction and the Y-direction. In a cross-sectional diagram, the active pattern 140 may surround the back gate structure 120. In the cross-sectional diagram, the active pattern 140 may have a U-shape. For example, the active pattern 140 may include a first vertical pattern 142, a second vertical pattern 144, and a horizontal pattern 146. The first vertical pattern 142 and the second vertical pattern 144 may be spaced apart from each other in the X-direction with the back gate structure 120 interposed therebetween, and may extend in the vertical direction. The horizontal pattern 146 may be disposed between the first vertical pattern 142 and the second vertical pattern 144, and may be disposed below the back gate structure 120. Upper surfaces of the first vertical pattern 142 and the second vertical pattern 144 may be coplanar with an upper surface of the back gate structure 120. A lower surface of the active pattern 140 may be in contact with the third conductive pattern 110c.

The active pattern 140 may be in contact with side surfaces 120a and 120b and a lower surface 120c of the back gate structure 120. For example, the first vertical pattern 142, the second vertical pattern 144 and the horizontal pattern 146 may be in contact with the side surface 120a, the side surface 120b and the lower surface 120c of the back gate structure 120, respectively. The first vertical pattern 142, the second vertical pattern 144 and the horizontal pattern 146 may have the same length in the Y-direction. The first vertical pattern 142, the second vertical pattern 144 and the horizontal pattern 146 may be continuous in terms of a material thereof. For example, the first vertical pattern 142, the second vertical pattern 144 and the horizontal pattern 146 may include the same material (e.g., a single crystal semiconductor material), and no boundary surface may be observed therebetween. A maximum horizontal width in the X-direction of an active pattern 140 may be the same as a distance between adjacent wordline structures 150.

Each of the active patterns 140 may include a first source/drain region in contact with the bitline structure 110, a second source/drain region in contact with the contact pattern 170, and a channel region between the first source/drain region and the second source/drain region. In an example embodiment, the first and second source/drain regions may have N-type conductivity. For example, the first and second source/drain regions may be doped with N-type impurities in a relatively high concentration, and the channel region may be doped with P-type impurities in a relatively low concentration.

The first vertical pattern 142 and the second vertical pattern 144 may be included in different vertical channel transistors, respectively. For example, the first vertical pattern 142, the bitline structure 110 and the wordline 154 may be included in a vertical channel transistor, and the second vertical pattern 144, the bitline structure 110 and the wordline 154 may be included in a vertical channel transistor separate from the vertical channel transistor. At least a portion of the horizontal pattern 146 may also function as a vertical channel transistor.

An area of a lower surface of the active pattern 140 may be greater than an area of an upper surface of the active pattern 140. For example, the sum of the areas of the lower surfaces of the first vertical pattern 142, the second vertical pattern 144 and the horizontal pattern 146 may be greater than the area of the upper surfaces of the first vertical pattern 142 and/or the second vertical pattern 144. In example embodiments, the active pattern 140 may be disposed between the first vertical pattern 142 and the second vertical pattern 144 and may include a horizontal pattern 146 in contact with the bitline structure 110, such that a contact area between the active pattern 140 and the bitline structure 110 may be increased. Accordingly, resistance between the active pattern 140 and the bitline structure 110 may be reduced, which may improve electrical properties of the semiconductor device 100. Also, because the contact area between the active pattern 140 and the bitline structure 110 is increased, the semiconductor device 100 having a smaller design rule may be implemented.

In example embodiments, the active patterns 140 may include a single crystal semiconductor material. The single crystal semiconductor material may include group IV semiconductor, group III-V compound semiconductor, or group II-VI compound semiconductor, and may be, for example, a single crystal semiconductor including at least one of silicon, silicon carbide, germanium, or silicon-germanium.

However, in some example embodiments, the active patterns 140 may include at least one of a polycrystalline semiconductor material layer, an oxide semiconductor material layer such as indium gallium zinc oxide (IGZO), or a two-dimensional material layer such as MoS₂.

The oxide semiconductor layer may be indium gallium zinc oxide (IGZO). However, example embodiments are not limited thereto. For example, the oxide semiconductor layer may include at least one of indium tungsten oxide (IWO), indium tin gallium oxide (ITGO), indium aluminium zinc oxide (IAGO), indium gallium oxide (IGO), indium tin zinc oxide (ITZO), zinc tin oxide (ZTO), indium zinc oxide (IZO), ZnO, indium gallium silicon oxide (IGSO), indium oxide (InO), tin oxide (SnO), titanium oxide (TiO), zinc oxynitride (ZnON), magnesium zinc oxide (MgZnO), indium zinc oxide (InZnO), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), or indium gallium silicon oxide (InGaSiO).

The two-dimensional material layer may include at least one of a transition metal dichalcogenide material layer (TMD material layer), a black phosphorous material layer, or a hexagonal boron-nitride material layer (hBN material layer) which may have semiconductor properties. For example, the two-dimensional material layer may include at least one of BiOSe, Crl, WSe2, MoS2, TaS, WS, SnSe, ReS, β-SnTe, MnO, AsS, P(black), InSe, h-BN, GaSe, GaN, SrTiO, MXene, or Janus 2D materials which may form the two-dimensional material.

The wordline structures 150 may intersect with the bitline structures 110. For example, the wordline structures 150 may extend in the Y-direction and may be spaced apart from each other in the X-direction. The wordline structures 150 may be alternately disposed with the back gate structure 120 in the X-direction.

The wordline structure 150 may include a gate dielectric layer 152, a wordline 154, a gap-fill insulating layer 156, and a gate capping layer 158. The wordline structure 150 may have two wordlines 154 spaced apart from each other in the X-direction. The wordlines 154 may be disposed on the bitline structure 110 and on both side surfaces of the back gate structures 120. In an example embodiment, an upper surface of the wordline 154 may be concave, but example embodiments are not limited thereto. Active patterns 140 may be disposed between respective ones of the back gate structures 120 and corresponding ones of the wordlines 154, respectively. The wordline 154 may also be referred to as a “gate electrode” or a “front gate electrode.”

The wordline 154 may include doped polysilicon, metal, conductive metal nitride, metal-semiconductor compound, conductive metal oxide, conductive graphene, carbon nanotube, or a combination thereof. For example, the wordline 154 may be formed of or include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotubes or combinations thereof, but example embodiments are not limited thereto. The wordline 154 may include a single layer or multiple layers of the materials described above. In an example embodiment, the wordline 154 may be formed of or include the same material as the back gate electrode 124, but example embodiments are not limited thereto, and the wordline 154 may include a different material.

FIG. 1 illustrates the example in which two wordlines 154 are disposed on both sides of the back gate electrode 124, respectively, but example embodiments are not limited thereto. In an example embodiment, the back gate electrodes 124 may not be provided. In an example embodiment, the back gate structure 120 may be replaced with the wordline structure 150. For example, as in the plan diagram, the semiconductor device 100 may have a double gate structure in which the wordline 154 is disposed on both sides of the active pattern 140.

The gate dielectric layer 152 may extend along a side surface of the wordline 154 in the Y-direction. The gate dielectric layer 152 may be disposed between the active pattern 140 and the wordline 154. For example, the gate dielectric layer 152 may be in contact with the first vertical pattern 142 or the second vertical pattern 144 of the active pattern 140. A vertical length of the gate dielectric layer 152 may be greater than a vertical length of the wordline 154. For example, an upper surface of the gate dielectric layer 152 may be positioned at a level higher than a level of an upper surface of the wordline 154, and a lower surface of the gate dielectric layer 152 may be positioned at a level lower than a level of a lower surface of the wordline 154. In an example embodiment, the lower surface of the gate dielectric layer 152 may be in contact with the third conductive pattern 110c. In some example embodiments, the back gate dielectric layer 122 and the gate dielectric layer 152 may be referred to as the first gate dielectric layer and the second gate dielectric layer, respectively, or vice versa.

In an example, each of the gate dielectric layers 152 may be configured as a tunnel dielectric layer not including a data storage layer. For example, each of the gate dielectric layers 152 may include at least one of silicon oxide or a high-κ dielectric. The high-κ dielectric may include metal oxide or metal oxynitride. For example, the high-κ dielectric may be formed of or include HfO₂, HfSiO, HfSiON, HfTaO, HfTIO, HfZrO, ZrO₂, Al₂O₃, or a combination thereof, but example embodiments are not limited thereto. Each of the gate dielectric layers 152 may be formed as a single layer or multiple layers of the materials described above.

In another example, each of the gate dielectric layers 152 may include a data storage layer and a dielectric layer. For example, each of the gate dielectric layers 152 may include a ferroelectric layer which may have polarization properties depending on an electric field and may have a remnant polarization due to a dipole even in the absence of an external electric field. Data may be written using the polarization state in the ferroelectric layer. Accordingly, each of the gate dielectric layers 152 may include a ferroelectric layer which may be referred to as a data storage layer. The ferroelectric layer, which may be the data storage layer, may include Hf-based compound, Zr-based compound and/or Hf—Zr-based compound. For example, the Hf-based compound may be a HfO-based ferroelectric material, the Zr-based compound may include a ZrO-based ferroelectric material, and the Hf—Zr-based compound may include a HZO (hafnium zirconium oxide)-based ferroelectric material. The ferroelectric layer, which may be the data storage layer, may include a ferroelectric material doped with impurities, for example, at least one of C, Si, Mg, Al, Y, N, Ge, Sn, Gd, La, Sc or Sr. For example, the ferroelectric layer, which may be the data storage layer, may be a material in which at least one of HfO₂, ZrO₂ or HZrO is doped with impurities such as at least one of C, Si, Mg, Al, Y, N, Ge, Sn, Gd, La, Sc or Sr, for example.

In the gate dielectric layers 152, the data storage layer is not limited to the material described above and may include a material which may store data.

The gap-fill insulating layer 156 may extend between adjacent wordlines 154 in the Y-direction and may be spaced apart from each other in the X-direction. The gap-fill insulating layer 156 may be in contact with side surfaces of adjacent wordlines 154 opposing each other and may be in contact with upper surfaces of the adjacent wordlines 154. A vertical length of the gap-fill insulating layer 156 may be greater than a vertical length of the wordlines 154. For example, an upper surface of the gap-fill insulating layer 156 may be positioned at a level higher than a level of the upper surface of the wordline 154, and a lower surface of the gap-fill insulating layer 156 may be positioned at a level lower than a level of the lower surface of the wordline 154.

The gate capping layer 158 may be disposed below the wordline 154, and may be in contact with a lower surface of the wordline 154 and a side surface of the gate dielectric layer 152. The lower surface of the gate capping layer 158 may be coplanar with a lower surface of the active pattern 140 and a lower surface of an insulating pattern 21. The structures of the gap-fill insulating layer 156 and the gate capping layer 158 illustrated in FIG. 1B are merely an example, and example embodiments are not limited thereto.

The gap-fill insulating layer 156 and the gate capping layer 158 may include silicon oxide, silicon nitride, silicon oxynitride, silicon carbonitride, low-K dielectric, or a combination thereof. For example, the gap-fill insulating layer 156 may include silicon oxide, and the gate capping layer 158 may include silicon nitride.

In some example embodiments, the back gate structure 120 and the wordline structure 150 may be referred to as a first gate structure and a second gate structure, respectively, or vice versa. The back gate electrode 124 and the wordline 154 may be referred to as a first gate electrode and a second gate electrode, respectively, or vice versa.

The semiconductor device 100 according to some example embodiments may further include insulating patterns 21. In the plan diagram, the insulating patterns 21 may cover a side surface of the back gate structure 120 and may be disposed between the active patterns 140. The insulating patterns 21 may be spaced apart from each other in the Y-direction along the back gate structure 120. In an example embodiment, a horizontal width in the X-direction of the insulating pattern 21 may be the same as a horizontal width in the X-direction of the active pattern 140. For example, in the plan diagram, both side surfaces of the insulating pattern 21 may be coplanar with both side surfaces of the active pattern 140, respectively.

In the cross-sectional diagram, the insulating pattern 21 may surround the back gate structure 120. For example, the insulating pattern 21 may include a first vertical insulating pattern 23, a second vertical insulating pattern 25, and a horizontal insulating pattern 27. The first vertical insulating pattern 23 and the second vertical insulating pattern 25 may be spaced apart from each other in the X-direction with the back gate structure 120 interposed therebetween, and may extend in the vertical direction. The horizontal insulating pattern 27 may be disposed between the first vertical insulating pattern 23 and the second vertical insulating pattern 25, and may be disposed below the back gate structure 120. Upper surfaces of the first vertical insulating pattern 23 and the second vertical insulating pattern 25 may be coplanar with an upper surface of the back gate structure 120. A lower surface of the insulating pattern 21 may be in contact with the lower insulating layer 101.

The insulating pattern 21 may be in contact with the side surfaces 120a and 120b and the lower surface 120c of the back gate structure 120. For example, the first vertical insulating pattern 23, the second vertical insulating pattern 25 and the horizontal insulating pattern 27 may be in contact with the side surface 120a, the side surface 120b and the lower surface 120c of the back gate structure 120, respectively. The first vertical insulating pattern 23 and the second vertical insulating pattern 25 may also be in contact with the corresponding gate dielectric layers 152, respectively.

An area of a lower surface of the insulating pattern 21 may be greater than an area of an upper surface of the insulating pattern 21. For example, the sum of the areas of the lower surfaces of the first vertical insulating pattern 23, the second vertical insulating pattern 25, and the horizontal insulating pattern 27 may be greater than the area of the upper surfaces of the first vertical insulating pattern 23 and/or the second vertical insulating pattern 25.

The insulating pattern 21 may include silicon oxide, silicon nitride, silicon oxynitride, silicon carbonitride, low-K dielectric, or a combination thereof. For example, the insulating pattern 21 may include silicon oxide. In an example embodiment, the insulating pattern 21 may include the same material as the back gate dielectric layer 122 and the gate dielectric layer 152, and density of the insulating pattern 21 may be less than density of the back gate dielectric layer 122 and/or the gate dielectric layer 152.

The contact patterns 170 may be disposed on the active patterns 140 and may be electrically connected to the active patterns 140. A lower surface of the contact patterns 170 may be in contact with the back gate dielectric layer 122, the active pattern 140, and the gate dielectric layer 152. The contact patterns 170 may electrically connect the active patterns 140 and the data storage structure 180. In an example embodiment, each active pattern 140 may be electrically connected to two contact patterns 170. For example, upper surfaces of a first vertical pattern 142 and a second vertical pattern 144 of the active pattern 140 may be in contact with the contact patterns 170, respectively.

The contact patterns 170 may include a conductive material, for example, doped single crystal silicon, doped polycrystalline silicon, metal, conductive metal nitride, metal-semiconductor compound, conductive metal oxide, conductive graphene, carbon nanotube, or a combination thereof. In an example embodiment, the contact patterns 170 may include first to fourth contact layers 170a, 170b, 170c, and 170d stacked in order. For example, the first contact layer 170a may include undoped polycrystalline silicon, the second contact layer 170b may include doped polycrystalline silicon, the third contact layer 170c may include a silicide material, and the fourth contact layer 170d may include metal. However, in example embodiments, the number of layers and the type of materials of the contact patterns 170 may be varied.

The semiconductor device 100 may further include insulating structures 175 disposed between the contact patterns 170. Each of the insulating structures 175 may extend vertically and may be in contact with at least one of the back gate dielectric layer 122, the upper capping layer 126, the gate dielectric layer 152, or the gap-fill insulating layer 156. The insulating structures 175 may spatially isolate the contact patterns 170 and may electrically insulate the contact patterns 170 from each other.

The data storage structures 180 may include first electrodes 182 electrically connected to the contact patterns 170, second electrodes 186 covering the first electrodes 182, and a dielectric layer 184 between the first electrodes 182 and the second electrode 186.

In an example embodiment, the data storage structures 180 may be capacitors storing data in a DRAM. For example, the dielectric layer 184 of the data storage structures 180 may be configured as a capacitor dielectric layer of a DRAM, and the dielectric layer 184 may include high-κ dielectric, silicon oxide, silicon nitride, silicon oxynitride, or a combination thereof.

In some example embodiments, the data storage structures 180 may be used in a memory other than a DRAM. For example, the dielectric layer 184 of the data storage structures 180 may be configured as a capacitor dielectric layer of a ferroelectric memory (FeRAM). In this case, the dielectric layer 184 may be configured as a ferroelectric layer for recording data using a polarization state. In another example embodiment, the ferroelectric layer may also include a lower dielectric layer including at least one of silicon oxide or high-k dielectric and a ferroelectric layer disposed on the lower dielectric layer.

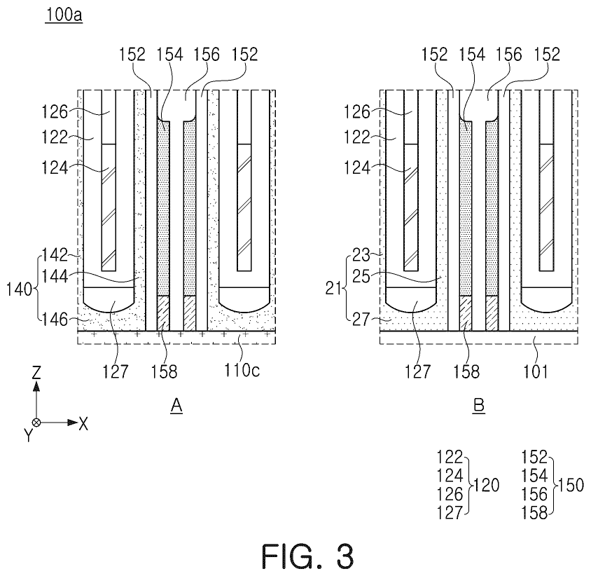

FIGS. 3 to 10C are plan diagrams illustrating semiconductor devices according to an example embodiment.

Referring to FIG. 3, the semiconductor device 100a may include a back gate structure 120 and an active pattern 140 surrounding the back gate structure 120. In an example embodiment, the back gate structure 120 may further include a spacer layer 127 disposed below the back gate dielectric layer 122. The spacer layer 127 may be in contact with the active pattern 140 and may be disposed between a portion of the active pattern 140 and the back gate dielectric layer 122. The spacer layer 127 may be used to ensure a spacing distance between the back gate electrode 124 and the bitline structure 110. Because the spacer layer 127 is disposed between the back gate electrode 124 and the bitline structure 110, electrical coupling between the back gate electrode 124 and the bitline structure 110 may be reduced or prevented. The spacer layer 127 may include silicon oxide, silicon nitride, silicon oxynitride, silicon carbonitride, low-K dielectric, or a combination thereof.

In an example embodiment, the wordline structure 150 may further include a spacer layer disposed below the wordlines 154. For example, the spacer layer may be in contact with the third conductive pattern 110c of the bitline structure 110, and may be disposed between the third conductive pattern 110c and the gate dielectric layer 152 and between the third conductive pattern 110c and the wordlines 154. Gate capping layers 158 may not be provided, and the gate dielectric layer 152 may extend between an upper surface of the spacer layer and lower surfaces of the wordlines 154 and may have a U-shape.

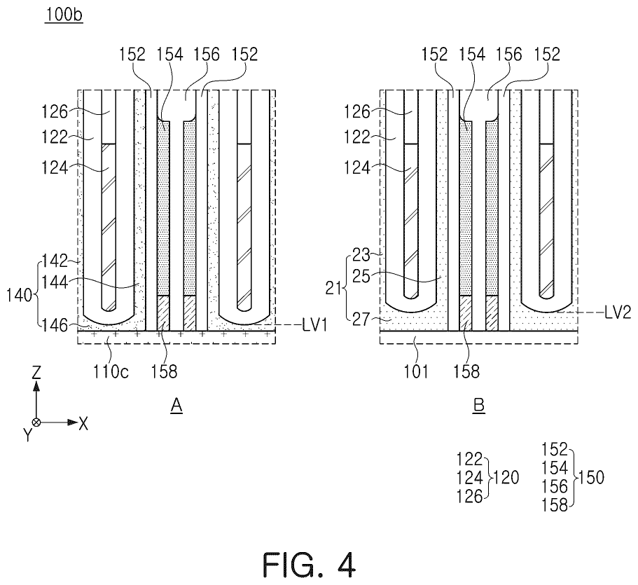

Referring to FIG. 4, a semiconductor device 100b may include a back gate structure 120 and an active pattern 140 surrounding the back gate structure 120. In an example embodiment, a height of the back gate structure 120 may not be constant. The back gate structure 120 may include a first portion in contact with the active pattern 140 and a second portion in contact with the insulating pattern 21. The first portion may be disposed at a first level LV1, and the second portion may be disposed at a second level LV2 different from the first level LV1. For example, the first level LV1 may be lower than the second level LV2.

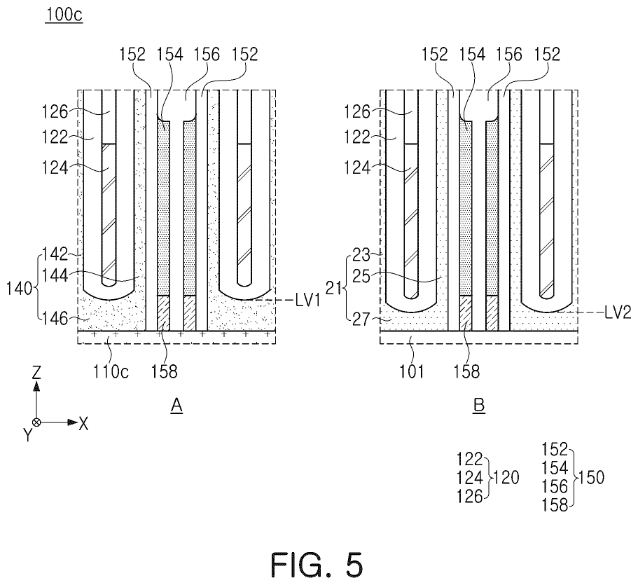

Referring to FIG. 5, a semiconductor device 100c may include a back gate structure 120 and an active pattern 140 surrounding the back gate structure 120. In an example embodiment, a height of the back gate structure 120 may not be constant. The back gate structure 120 may include a first portion in contact with the active pattern 140 and a second portion in contact with the insulating pattern 21. The first portion may be disposed at a first level LV1, and the second portion may be disposed at a second level LV2 lower than the first level LV1.

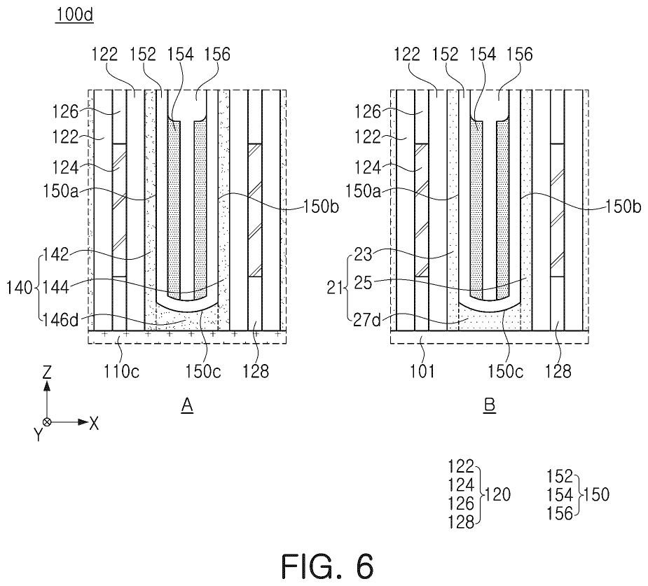

Referring to FIG. 6, the semiconductor device 100d may include a wordline structure 150 and an active pattern 140. In an example embodiment, in the cross-sectional diagram, the active pattern 140 may surround the wordline structure 150. A vertical length of the wordline structure 150 may be smaller than a vertical length of the back gate structure 120. For example, an upper surface of the wordline structure 150 may be coplanar with an upper surface of the back gate structure 120, and a lower end of the wordline structure 150 may be disposed at a level higher than a level of a lower end of the back gate structure 120.

The back gate structure 120 may further include a lower capping layer 128 disposed below the back gate electrode 124. The lower capping layer 128 may be in contact with an upper surface of the third conductive pattern 110c of the bitline structure 110 and side surfaces of the back gate dielectric layers 122. A lower surface of the lower capping layer 128 may be coplanar with a lower surface of the back gate dielectric layer 122. The lower capping layer 128 may include silicon oxide, silicon nitride, silicon oxynitride, silicon carbonitride, low-K dielectric, or a combination thereof.

In an example embodiment, the active pattern 140 may include a first vertical pattern 142, a second vertical pattern 144, and a horizontal pattern 146d. The first vertical pattern 142 and the second vertical pattern 144 may be spaced apart from each other in the X-direction with the wordline structure 150 interposed therebetween, and may extend in the vertical direction. The horizontal pattern 146d may be disposed between the first vertical pattern 142 and the second vertical pattern 144, and may be disposed below the wordline structure 150.

The active pattern 140 may be in contact with side surfaces 150a and 150b and a lower surface 150c of the wordline structure 150. For example, the first vertical pattern 142, the second vertical pattern 144, and the horizontal pattern 146d may be in contact with the side surface 150a, the side surface 150b, and the lower surface 150c of the wordline structure 150, respectively. A maximum horizontal width of the active pattern 140 in the X-direction may be the same as a distance between adjacent back gate structures 120.

In the cross-sectional diagram, the insulating pattern 21 may surround the wordline structure 150. For example, the insulating pattern 21 may include the first vertical insulating pattern 23, the second vertical insulating pattern 25, and the horizontal insulating pattern 27d. The first vertical insulating pattern 23 and the second vertical insulating pattern 25 may be spaced apart from each other in the X-direction with the wordline structure 120 interposed therebetween, and may extend in the vertical direction. The horizontal insulating pattern 27d may be disposed between the first vertical insulating pattern 23 and the second vertical insulating pattern 25, and may be disposed below the wordline structure 150.

The insulating pattern 21 may be in contact with the side surfaces 150a and 150b and a lower surface 150c of the wordline structure 150. For example, the first vertical insulating pattern 23, the second vertical insulating pattern 25 and the horizontal insulating pattern 27d may be in contact with the side surface 150a, the side surface 150b and the lower surface 150c of the wordline structure 150, respectively.

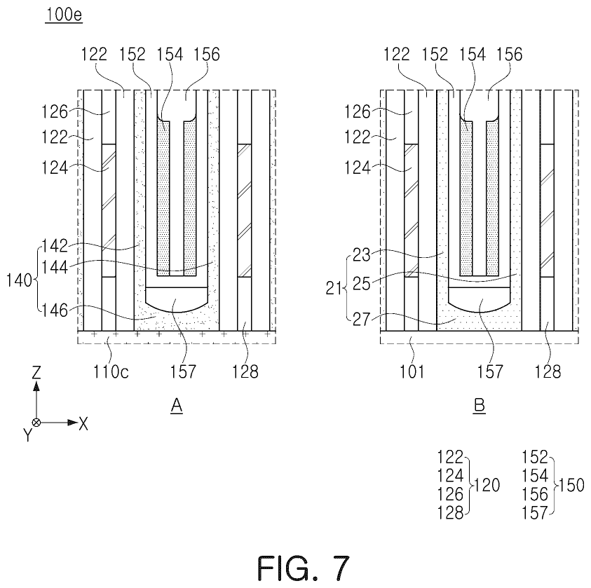

Referring to FIG. 7, the semiconductor device 100e may include a wordline structure 150 and an active pattern 140 surrounding the wordline structure 150. In an example embodiment, the wordline structure 150 may further include a spacer layer 157 disposed below a gate dielectric layer 152. The spacer layer 157 may be in contact with the active pattern 140 and may be disposed between a portion of the active pattern 140 and the gate dielectric layer 152. The spacer layer 157 may be used to ensure a spacing distance between the wordline 154 and the bitline structure 110. Because the spacer layer 157 is disposed between the wordline 154 and the bitline structure 110, electrical coupling between the wordline 154 and the bitline structure 110 may be reduced or prevented. The spacer layer 157 may include silicon oxide, silicon nitride, silicon oxynitride, silicon carbonitride, low-K dielectric, or a combination thereof.

In an example embodiment, the back gate structure 120 may further include a spacer layer disposed below the back gate electrode 124. The spacer layer may be in contact with the third conductive pattern 110c of the bitline structure 110, and may be disposed between the third conductive pattern 110c and the back gate dielectric layers 122 and between the third conductive pattern 110c and the back gate electrode 124. A lower capping layer 128 may not be provided, and the back gate dielectric layer 122 may extend between an upper surface of the spacer layer and a lower surface of the back gate electrode 124 and may have a U-shape.

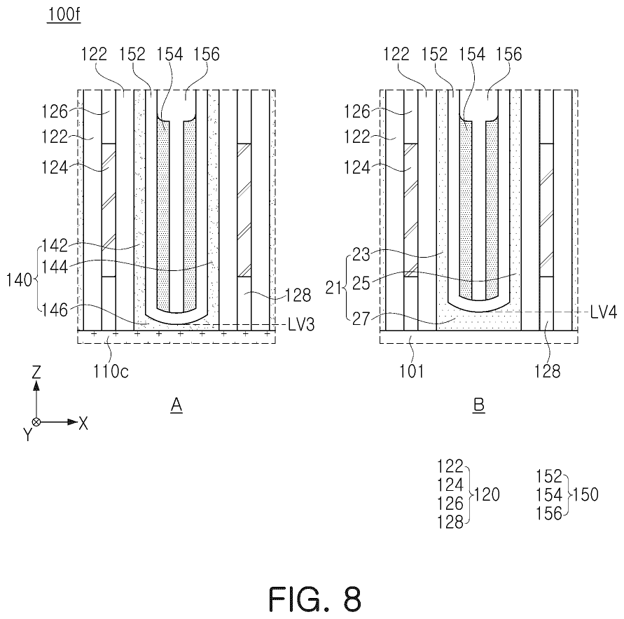

Referring to FIG. 8, a semiconductor device 100f may include a wordline structure 150 and an active pattern 140 surrounding the wordline structure 150. In an example embodiment, a height of the wordline structure 150 may not be constant. The wordline structure 150 may include a first portion in contact with the active pattern 140 and a second portion in contact with the insulating pattern 21. The first portion may be disposed at a third level LV3, and the second portion may be disposed at a fourth level LV4 different from the third level LV3. For example, the third level LV3 may be lower than the fourth level LV4.

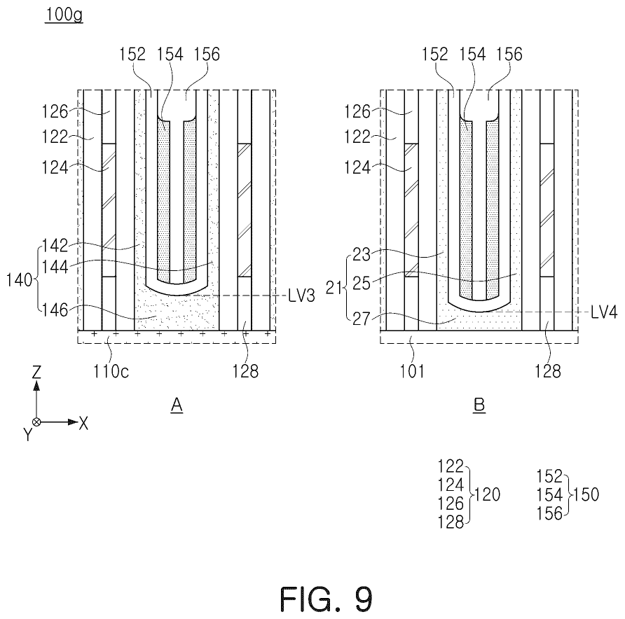

Referring to FIG. 9, a semiconductor device 100g may include a wordline structure 150 and an active pattern 140 surrounding the wordline structure 150. In an example embodiment, a height of the wordline structure 150 may not be constant. The wordline structure 150 may include a first portion in contact with the active pattern 140 and a second portion in contact with the insulating pattern 21. The first portion may be disposed at a third level LV3, and the second portion may be disposed at a fourth level LV4 lower than the third level LV3.

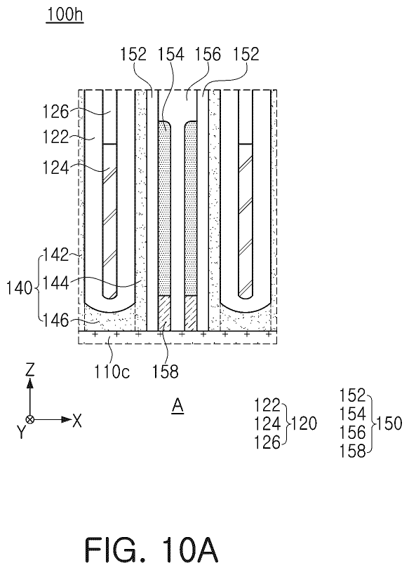

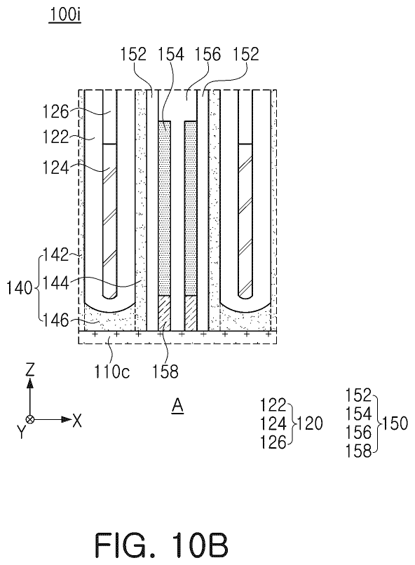

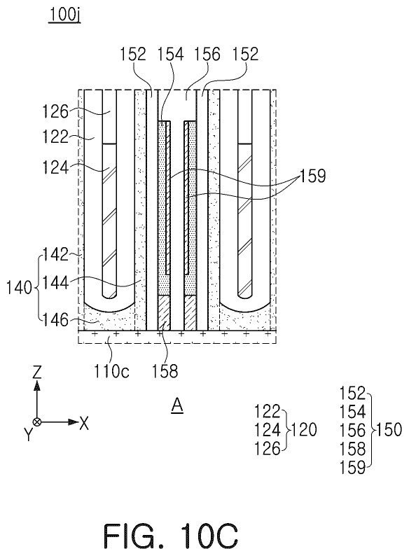

FIGS. 10A to 10C illustrate wordlines according to some example embodiments.

Referring to FIG. 10A, a semiconductor device 100h may include wordlines 154. In an example embodiment, an upper surface of the wordlines 154 may include a curved surface.

Referring to FIG. 10B, a semiconductor device 100i may include wordlines 154. In an example embodiment, an upper surface of the wordlines 154 may be substantially planar.

Referring to FIG. 10C, a wordline structure 150 of a semiconductor device 100j may further include liners 159 in contact with a side surface of the wordlines 154. The liners 159 may be in contact with side surfaces of adjacent wordlines 154 opposing each other and may be in contact with the gap-fill insulating layer 156. The liners 159 may be used to assure a spacing distance between adjacent wordlines 154. For example, the distance in the X-direction between the wordlines 154 may be increased by the liners 159, and electrical coupling between adjacent wordlines 154 may be reduced or prevented.

In an example embodiment, a vertical length of the liner 159 may be less than a vertical length of the wordline 154. For example, an upper surface of the liner 159 may be coplanar with an upper surface of the wordline 154, and a lower surface of the liner 159 may be disposed at a level higher than a level of a lower surface of the wordline 154. However, the structure of liner 159 illustrated in FIG. 10c is merely an example, but example embodiments are not limited thereto.

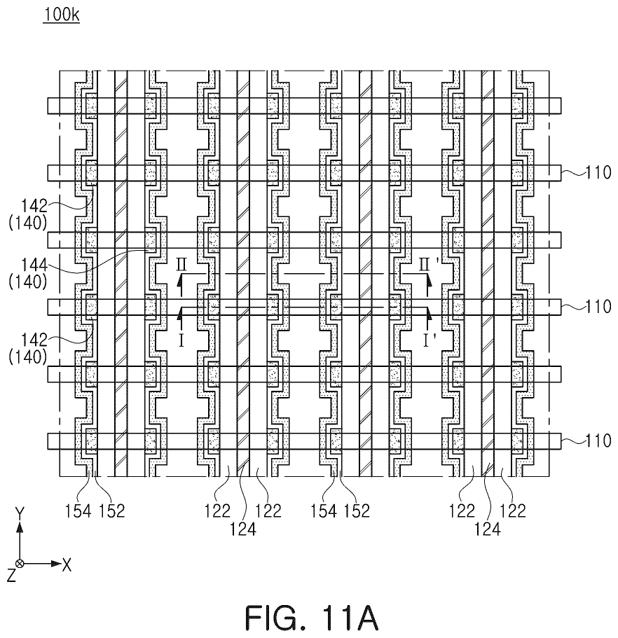

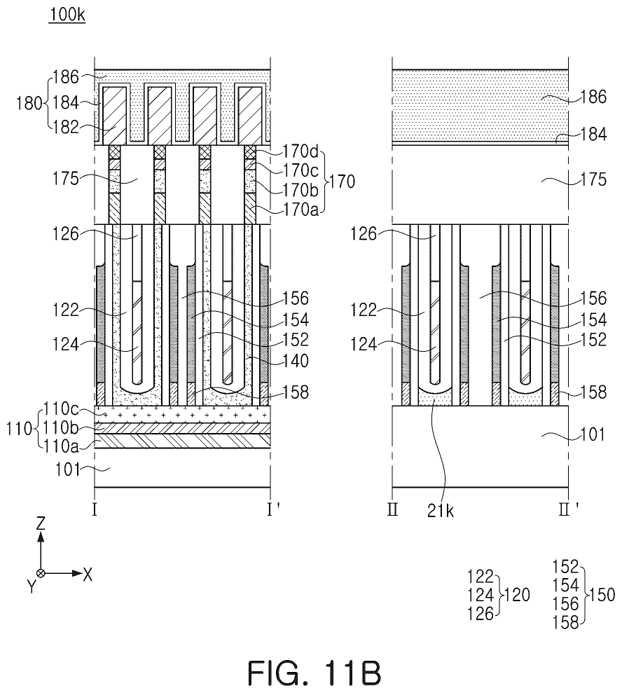

FIG. 11A is a plan diagram illustrating a semiconductor device according to an example embodiment. FIG. 11B is vertical cross-sectional diagrams illustrating the semiconductor device illustrated in FIG. 11A taken along lines I-I′ and II-II′.

Referring to FIGS. 11A and 11B, a semiconductor device 100k may include an insulating pattern 21k in contact with a back gate structure 120. In an example embodiment, the insulating pattern 21k may be disposed below the back gate structure 120 and may not be in contact with a side surface of the back gate structure 120. For example, the back gate dielectric layer 122 may be in contact with the gate dielectric layer 152, and the insulating pattern 21k may not be interposed between the back gate dielectric layer 122 and the gate dielectric layer 152. A vertical length of the insulating pattern 21k may be smaller than a vertical length of the back gate structure 120.

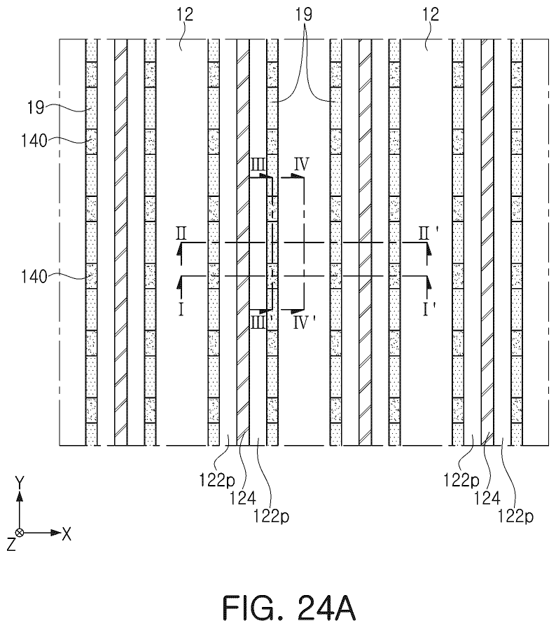

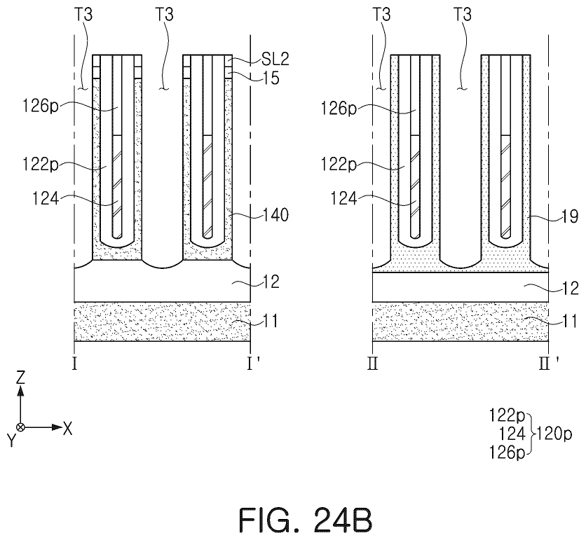

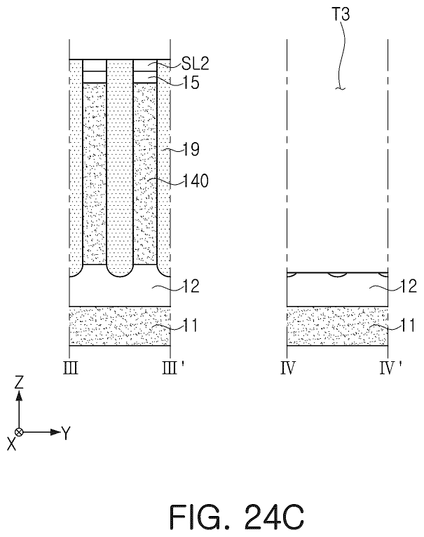

Referring to FIGS. 24A to 24C, after the etching process described below, the interlayer insulating layer 19 may be etched such that a side surface of the dielectric material layer 122p may be exposed. A second preliminary gate structure 150 may be formed on an exposed side surface of the dielectric material layer 122p. The etched interlayer insulating layer 19 may be referred to as an insulating pattern 21k.

In the plan diagram, the gate dielectric layer 152 and the wordline 154 may surround at least a portion of the active pattern 140. For example, an active pattern 140 and a wordline 154 may have a tri-gate structure. The tri-gate structure is a type of MOSFET with a gate on three sides. The active pattern 140 may have three side surfaces opposing the wordline 154. Because the active pattern 140 and the wordline 154 have a tri-gate structure, leakage current may be reduced and the short channel effect may be reduced.

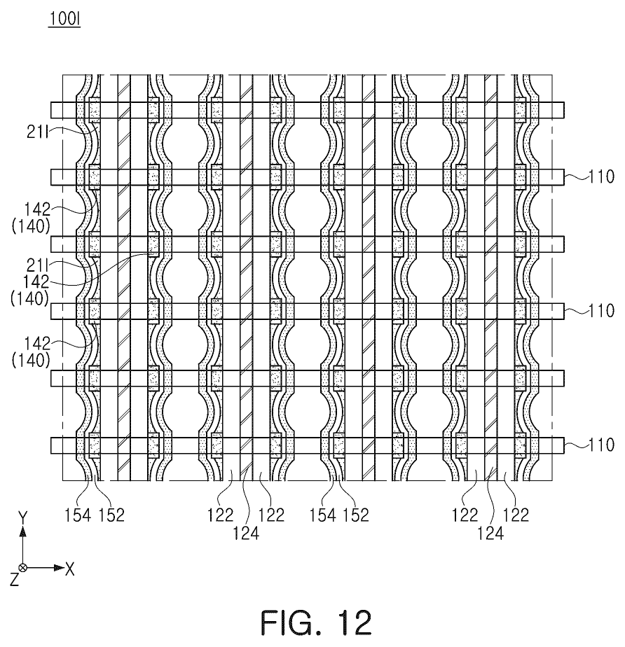

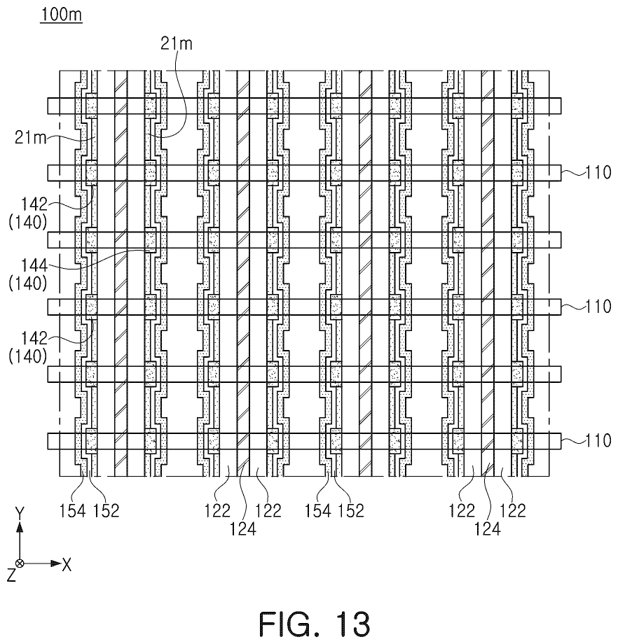

FIGS. 12 and 13 are plan diagrams illustrating a semiconductor device according to some example embodiments.

Referring to FIG. 12, a semiconductor device 100l may include active patterns 140 disposed on a side surface of the back gate structure 120 and insulating patterns 211 between the active patterns 140. Referring to FIGS. 24A to 24C, after the etching process described later, the interlayer insulating layer 19 may not be completely removed, and the interlayer insulating layer 19 remaining without being removed may be referred to as an insulating pattern 211.

When viewed in the plan diagram, a side surface of the insulating pattern 211 may have a curved surface. For example, one side surface of the insulating pattern 211 may be in contact with the back gate dielectric layer 122 and may be coplanar with the active pattern 140, and the other side surface opposite to the one side surface may have a curved surface. A maximum horizontal width in the X-direction of the insulating pattern 211 may be smaller than a horizontal width in the X-direction of the active pattern 140. For example, the active pattern 140 and the wordline 154 may have a tri-gate structure.

Referring to FIG. 13, a semiconductor device 100m may include insulating patterns 21m between the active patterns 140 and the active patterns 140 disposed on a side surface of the back gate structure 120.

As viewed in the plan diagram, a side surface of the insulating pattern 21m may be planar. For example, one side surface of the insulating pattern 21m may be in contact with the back gate dielectric layer 122 and may be coplanar with the active pattern 140, and the other side surface opposite to the one side surface may be planar. A maximum horizontal width in the X-direction of the insulating pattern 21m may be smaller than a horizontal width in the X-direction of the active pattern 140. For example, the active pattern 140 and the wordline 154 may have a tri-gate structure.

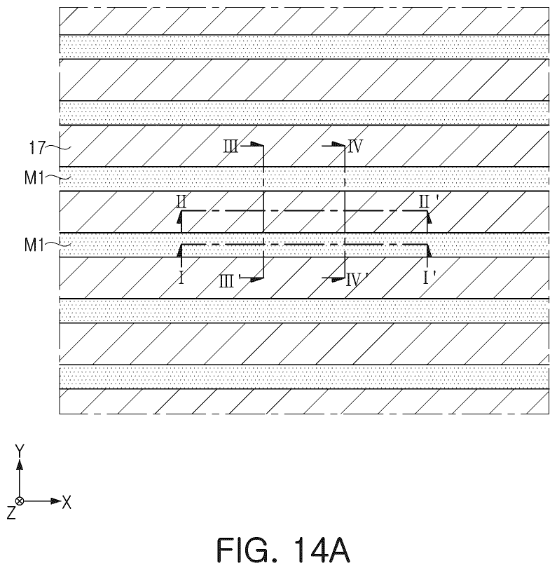

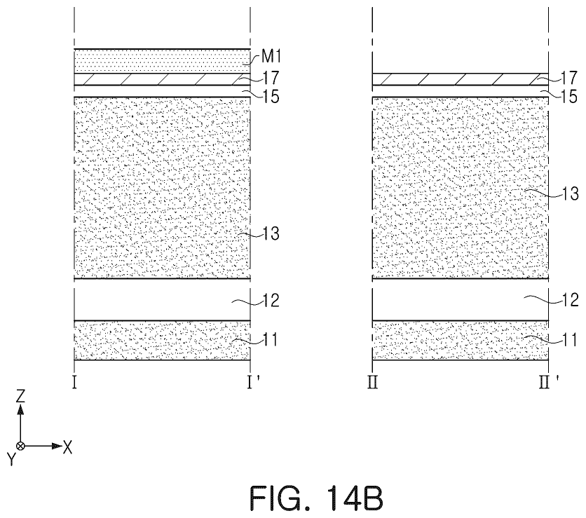

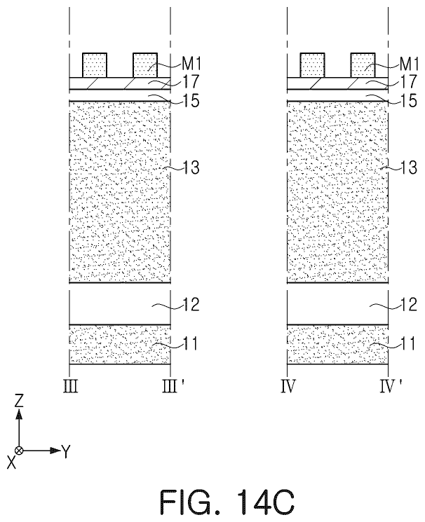

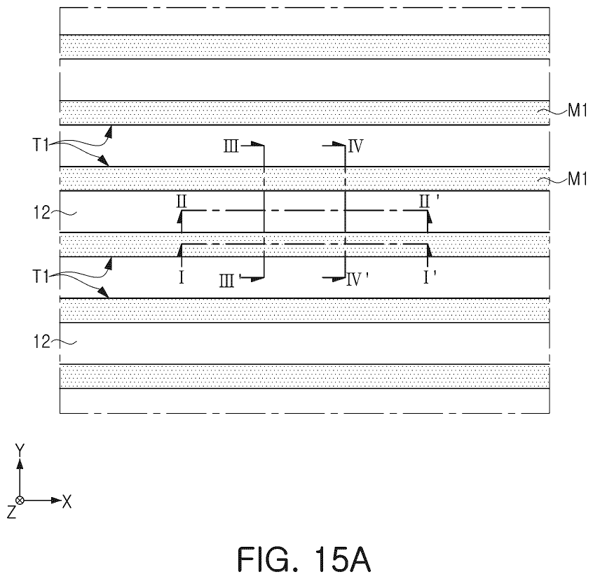

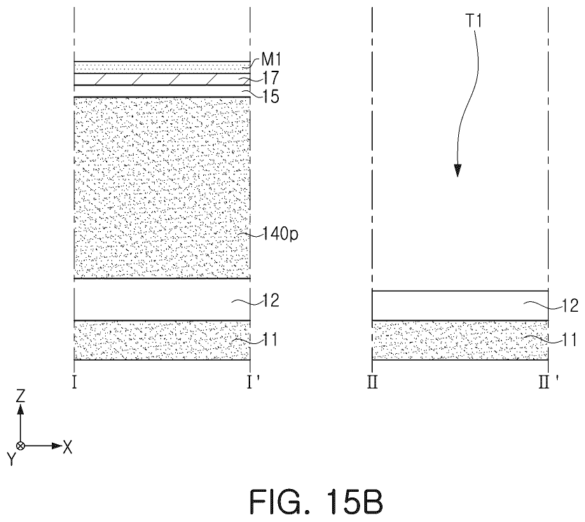

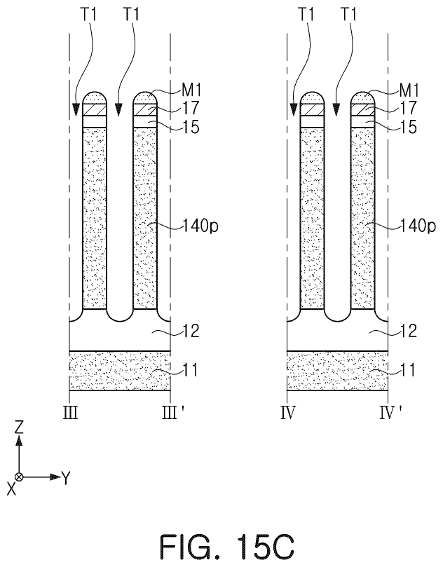

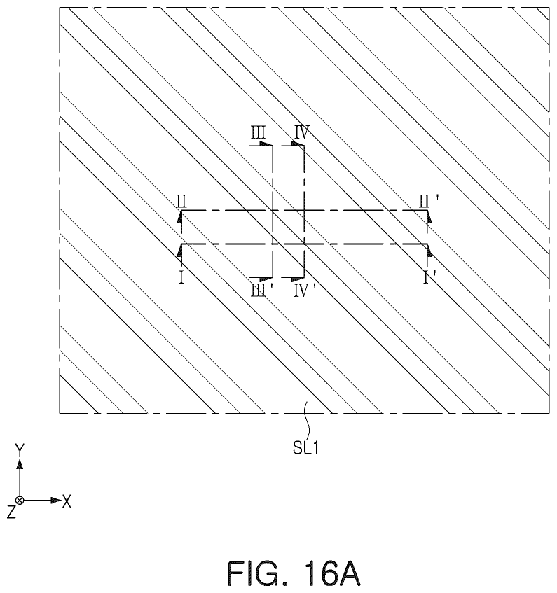

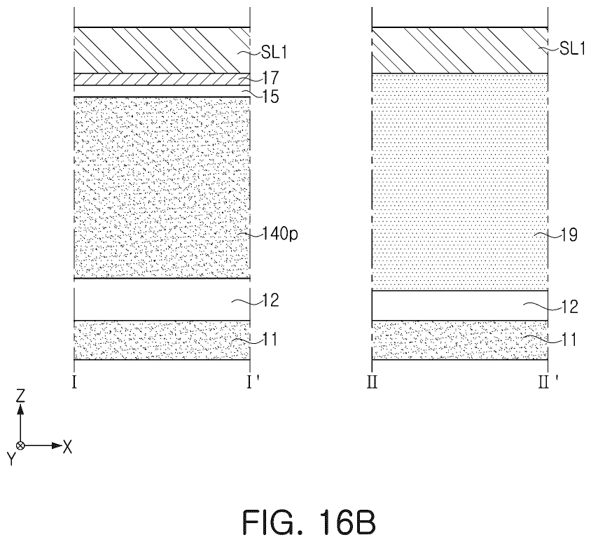

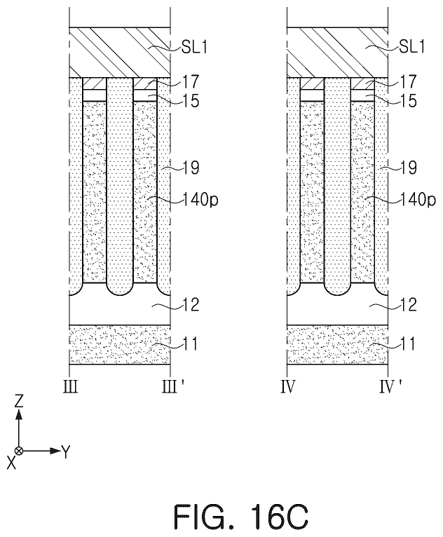

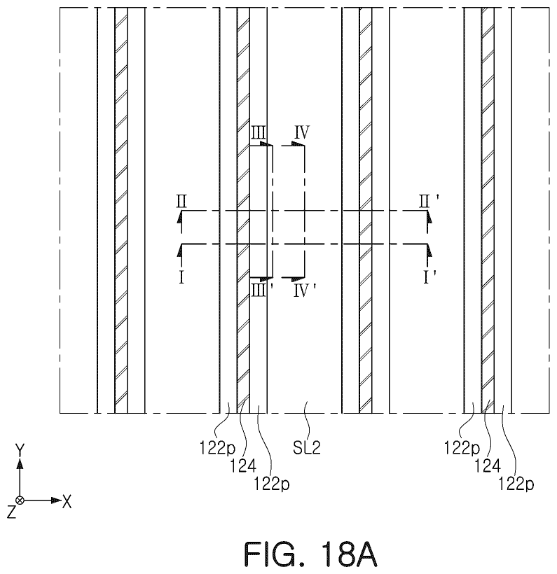

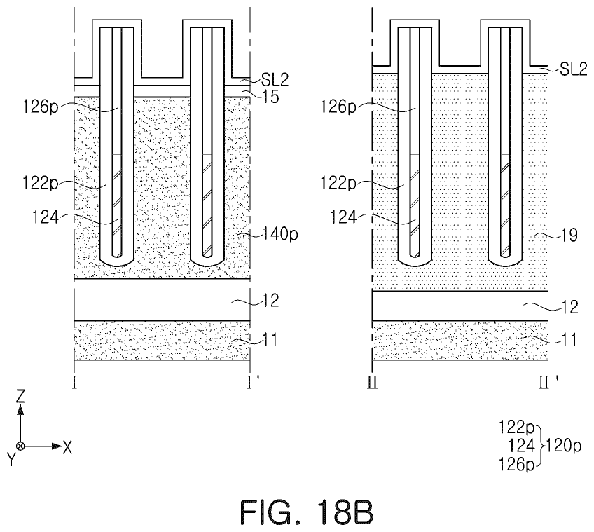

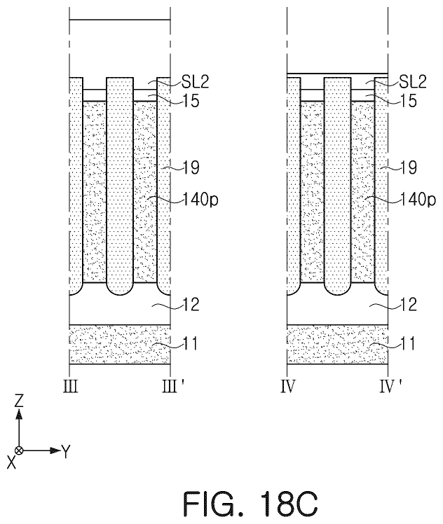

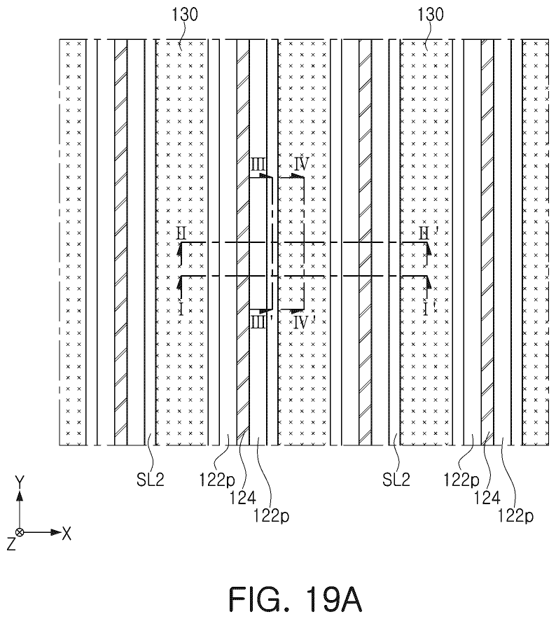

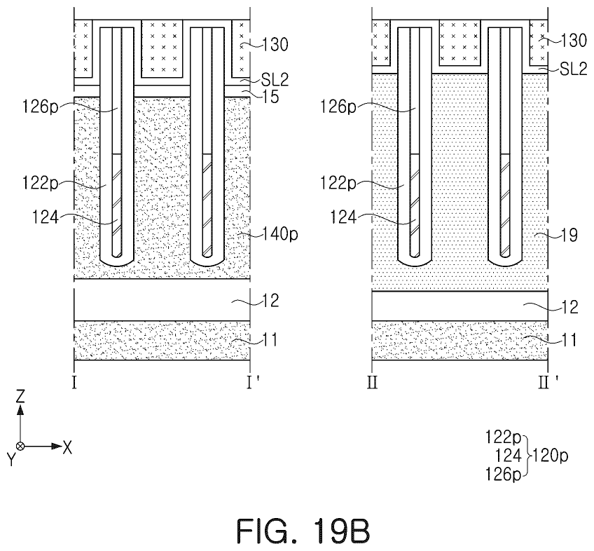

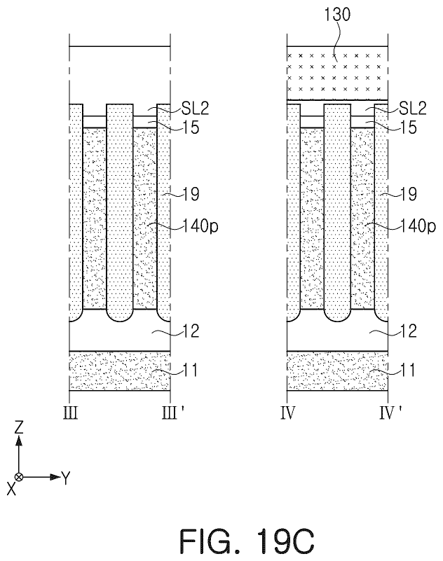

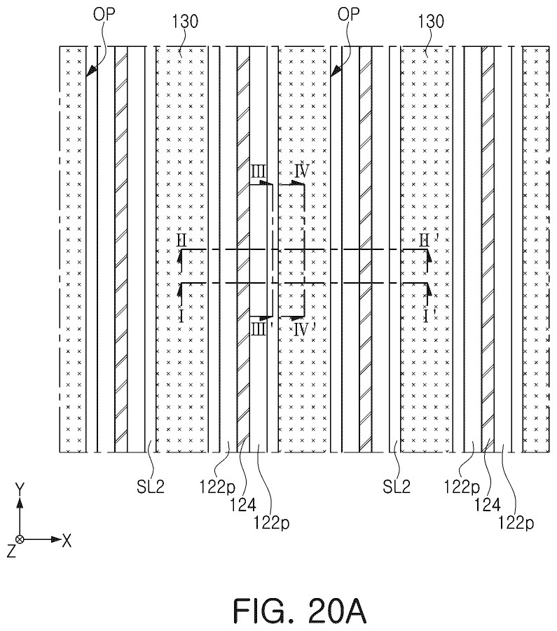

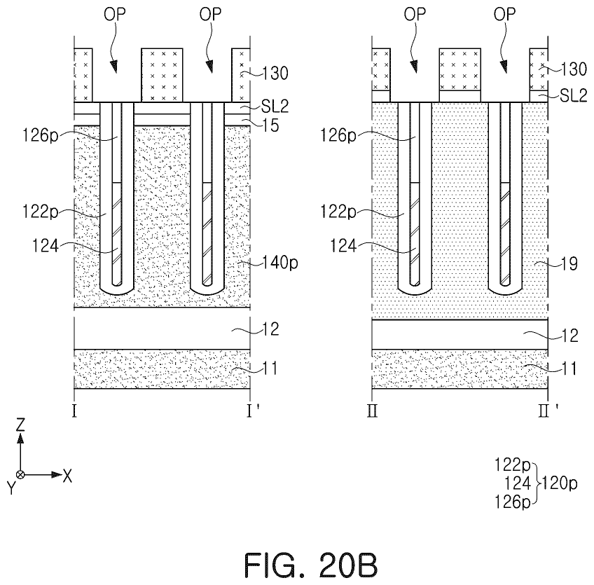

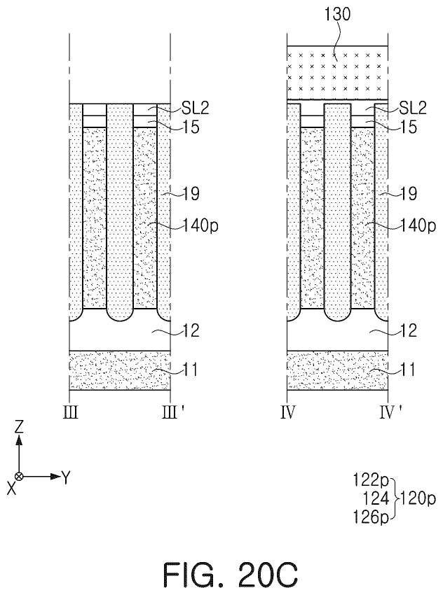

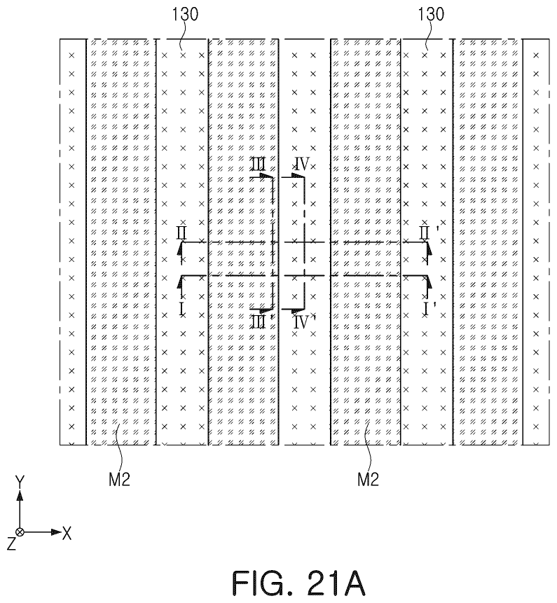

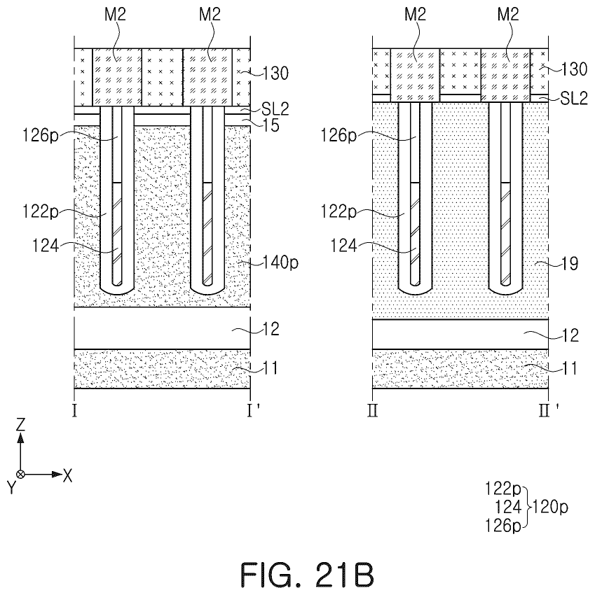

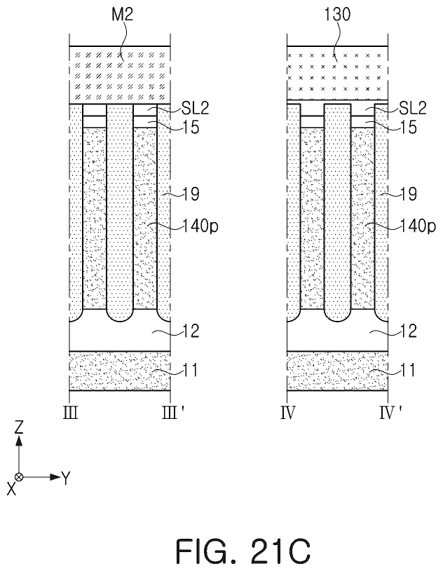

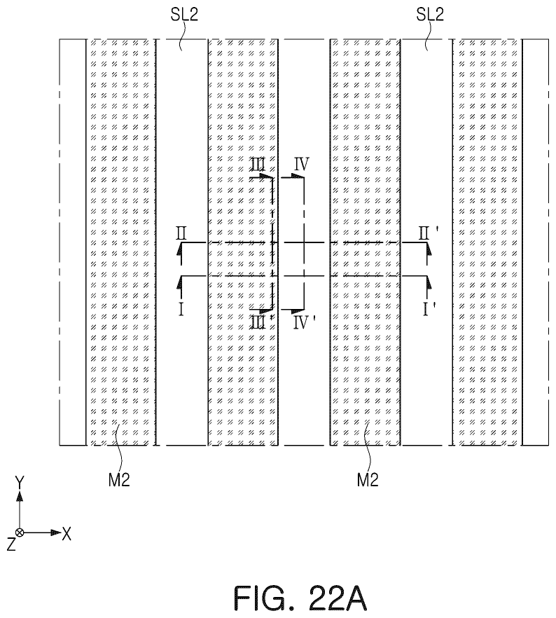

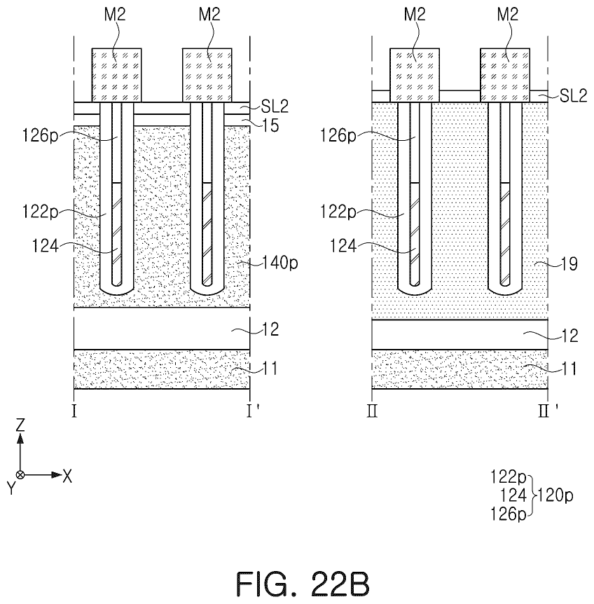

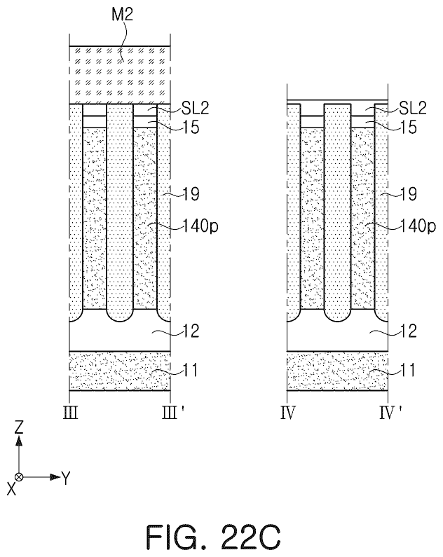

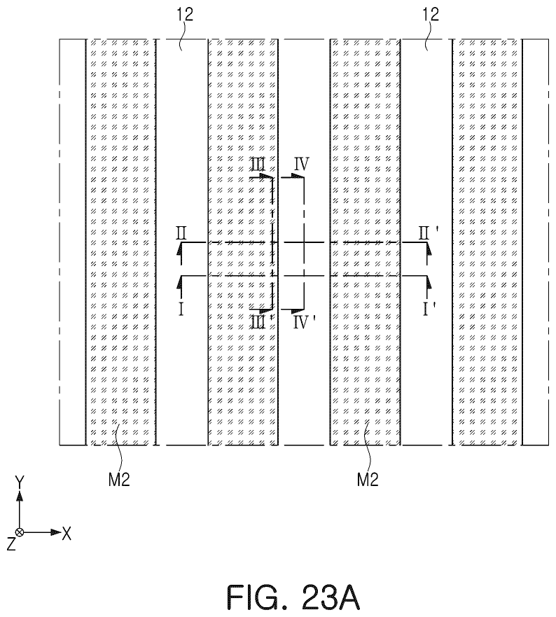

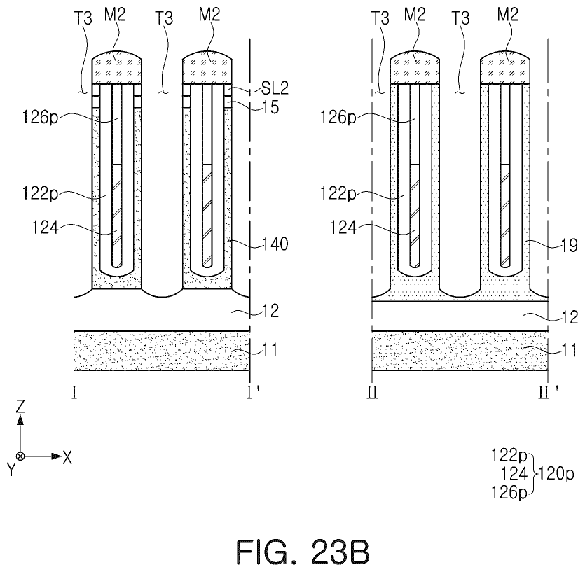

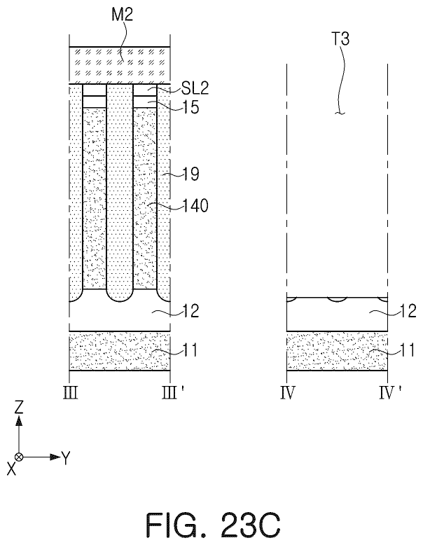

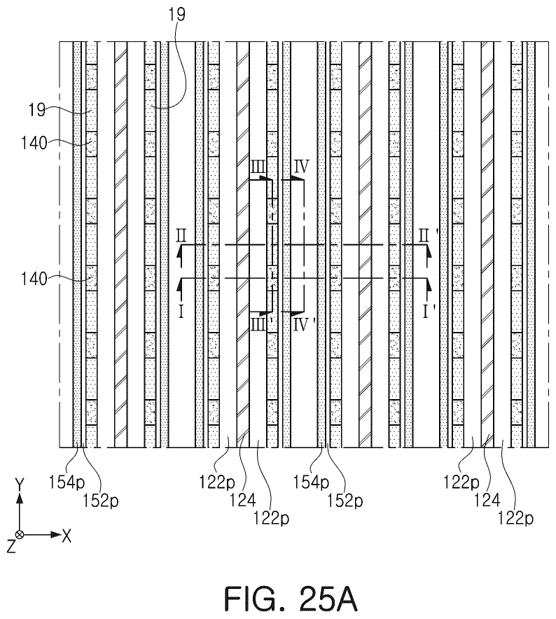

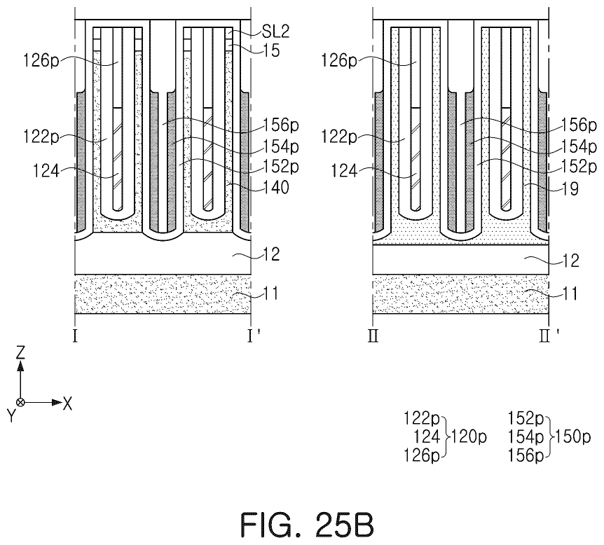

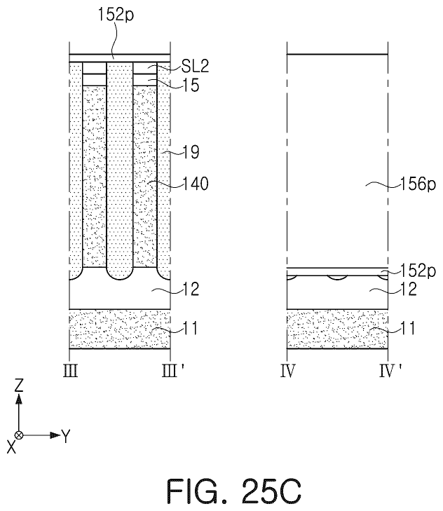

FIGS. 14A to 28 are plan diagrams and vertical cross-sectional diagrams illustrating processes of a method of manufacturing a semiconductor device in order according to an example embodiment. Specifically, FIGS. 14A, 15A, 16A, 17A, 18A, 19A, 20A, 21A, 22A, 23A, 24A and 25A are plan diagrams corresponding to FIG. 1A. FIGS. 14B, 15B, 16B, 17B, 18B, 19B, 20B, 21B, 22B, 23B, 24B, 25B, 26, 27 and 28 are vertical cross-sectional diagrams corresponding to FIG. 1B. FIG. 14C, FIG. 15C, FIG. 16C, FIG. 18C, FIG. 19C, FIG. 20C, FIG. 21C, FIG. 22C, FIG. 23C, FIG. 24C and FIG. 25C are vertical cross-sectional diagrams taken along lines III-III′ and IV-IV′ in FIG. 14A, FIG. 15A, FIG. 16A, FIG. 18A, FIG. 19A, FIG. 20A, FIG. 21A, FIG. 22A, FIG. 23A, FIG. 24A and FIG. 25A, respectively.

Referring to FIGS. 14A to 14C, a lower substrate 11, an intermediate layer 12, and a preliminary substrate 13 may be provided. The lower substrate 11, the intermediate layer 12, and the preliminary substrate 13 may be stacked in a vertical direction, and the intermediate layer 12 may be disposed between the lower substrate 11 and the preliminary substrate 13.

In an example embodiment, the lower substrate 11 and the preliminary substrate 13 may be semiconductor material layers, and the intermediate layer 12 may be an insulating layer. For example, the lower substrate 11, the intermediate layer 12, and the preliminary substrate 13 may be SOI (silicon on insulator) substrates, and the lower substrate 11 and the preliminary substrate 13 may include single crystal silicon. In an example embodiment, the lower substrate 11, the intermediate layer 12, and the preliminary substrate 13 may be semiconductor material layers, and the intermediate layer 12 and the preliminary substrate 13 may be formed on the lower substrate 11 by a deposition or epitaxial growth method. In an example embodiment, the preliminary substrate 13 may be configured as a bulk silicon substrate, and the lower substrate 11 and the intermediate layer 12 may not be provided.

A first buffer layer 15 and a second buffer layer 17 may be formed on the preliminary substrate 13. Each of the first buffer layer 15 and the second buffer layer 17 may include silicon oxide, silicon nitride, silicon oxynitride, silicon carbonitride, low-K dielectric, or a combination thereof. The first buffer layer 15 may include a material different from the second buffer layer 17. For example, the first buffer layer 15 may include silicon oxide, and the second buffer layer 17 may include silicon nitride. The first buffer layer 15 and the second buffer layer 17 illustrated in FIG. 14B are merely am example, and example embodiments are not limited thereto. In an example embodiment, a single buffer layer may be formed on the preliminary substrate 13.

First mask layers M1 may be formed on the second buffer layer 17. The first mask layers M1 may extend in the X-direction and may be spaced apart from each other in the Y-direction. The first mask layer M1 may include a material having etch selectivity with respect to the second buffer layer 17. In an example embodiment, the first mask layer M1 may include silicon oxide, silicon nitride, silicon oxynitride, silicon carbonitride, an amorphous carbon layer (ACL), low-K dielectric, or a combination thereof. In an example embodiment, the first mask layer M1 may include polysilicon, a metal, a conductive metal nitride, or a combination thereof.

Referring to FIGS. 15A to 15C, preliminary active patterns 140p may be formed by etching the preliminary substrate 13 using the first mask layer M1 as an etching mask. For example, channel trenches T1 may be formed in the preliminary substrate 13 by etching the preliminary substrate 13 using the first mask layer M1 as an etching mask. The channel trenches T1 may extend in the X-direction and may be spaced apart from each other in the Y-direction. The preliminary active patterns 140p may be defined by the channel trenches T1. For example, the preliminary active patterns 140p may extend in the X-direction and may be spaced apart from each other in the Y-direction. The channel trenches T1 may expose side surfaces of the preliminary active patterns 140p and an upper surface of the intermediate layer 12. The first mask layer M1 may be partially etched by an etching process.

In an example embodiment, a doping process may be performed on the preliminary active patterns 140p exposed by the channel trenches T1. For example, by performing a doping process such as a gas phase doping (GPD) process or a plasma doping (PLAD) process, the preliminary active patterns 140p may be doped with N-type impurities or P-type impurities.

Referring to FIGS. 16A to 16C, interlayer insulating layers 19 may be formed between the preliminary active patterns 140p. For example, after the first mask layer M1 is selectively removed, an insulating material layer may be formed to fill channel trenches T1 and to cover the second buffer layer 17. The interlayer insulating layers 19 may be formed by planarizing the insulating material layer such that an upper surface of the second buffer layer 17 may be exposed. For example, the planarization process may be performed through a chemical mechanical polishing (CMP) process. The interlayer insulating layers 19 may be coplanar with an upper surface of the second buffer layer 17. The interlayer insulating layers 19 may extend in the X-direction and may be spaced apart from each other in the Y-direction.

The interlayer insulating layers 19 may include silicon oxide, silicon nitride, silicon oxynitride, silicon carbonitride, low-K dielectric, or a combination thereof. For example, the interlayer insulating layers 19 may include silicon oxide.

A first sacrificial layer SL1 may be formed on the second buffer layer 17 and the interlayer insulating layers 19. The first sacrificial layer SL1 may include silicon oxide, silicon nitride, silicon oxynitride, silicon carbonitride, low-K dielectric, or a combination thereof. The first sacrificial layer SL1 may include a material having etch selectivity with respect to the interlayer insulating layers 19. For example, the first sacrificial layer SL1 may include silicon nitride.

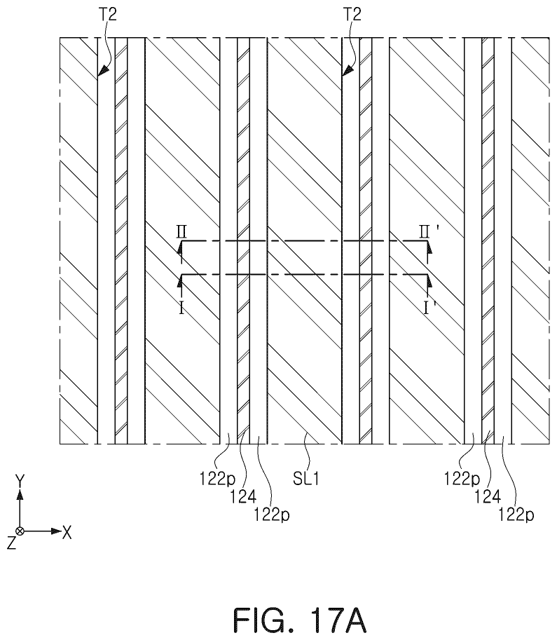

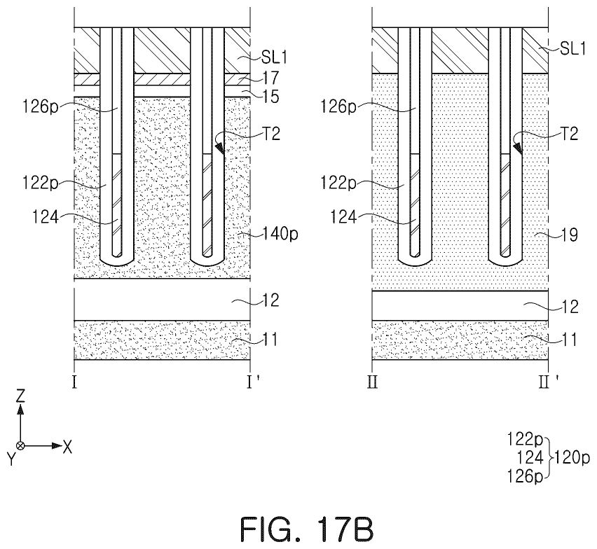

Referring to FIGS. 17A and 17B, first preliminary gate structures 120p intersecting the preliminary active patterns 140p may be formed. The forming the first preliminary gate structures 120p may include forming back gate trenches T2 in the preliminary active patterns 140p and filling the back gate trenches T2 with a dielectric material, a conductive material and an insulating material. For example, the back gate trenches T2 may extend in the Y-direction and may be spaced apart from each other in the X-direction. The back gate trenches T2 may expose side surfaces of the preliminary active patterns 140p and may expose internal walls of the first buffer layer 15, the second buffer layer 17, the interlayer insulating layer 19 and the first sacrificial layer SL1. Lower ends of the back gate trenches T2 may be disposed at a level higher than a level of an upper surface of the intermediate layer 12 so as not to expose the intermediate layer 12.

A dielectric material layer 122p may be deposited on an internal wall of the back gate trenches T2, a conductive material layer may be formed on the dielectric material layer 122p, and the conductive material layer may be etched-back, thereby forming back gate electrodes 124. Preliminary capping layers 126p may be formed on the back gate electrodes 124 to completely fill the back gate trenches T2.

In an example embodiment, the preliminary capping layers 126p may be formed through a deposition process, such as a chemical vapor deposition (CVD) process, an atomic layer deposition (ALD) process, or the like, and may be deposited from side surfaces of the dielectric material layer 122p and an upper surface of the back gate electrode 124. In an example embodiment, a seam may be formed in the preliminary capping layers 126p. The dielectric material layer 122p, the back gate electrode 124, and the preliminary capping layer 126p may form the first preliminary gate structure 120p. An upper surface of the first preliminary gate structure 120p may be coplanar with an upper surface of the first sacrificial layer SL1.

Referring to FIGS. 18A to 18C, the second buffer layer 17 and the first sacrificial layer SL1 may be removed. For example, the second buffer layer 17 and the first sacrificial layer SL1 may be removed by a wet etching process, and the first buffer layer 15 and the interlayer insulating layer 19 having etching selectivity with the second buffer layer 17 may not be etched. A side surface of an upper portion of the first preliminary gate structure 120p may be exposed by the etching process.

A second sacrificial layer SL2 may be formed on an upper portion of the exposed first preliminary gate structure 120p. The second sacrificial layer SL2 may be formed along surfaces of the first buffer layer 15, the interlayer insulating layer 19 and the first preliminary gate structure 120p. The second sacrificial layer SL2 may include silicon oxide, silicon nitride, silicon oxynitride, silicon carbonitride, low-K dielectric or a combination thereof. For example, the second sacrificial layer SL2 may include silicon oxide.

Referring to FIGS. 19A to 19C, gap-fill layers 130 may be formed between the first preliminary gate structures 120p. A gap-fill material layer may be deposited on the second sacrificial layer SL2 and a planarization process may be performed such that the second sacrificial layer SL2 may be exposed, thereby forming the gap-fill layers 130. The gap-fill layers 130 may extend in the Y-direction and may be spaced apart from each other in the X-direction.

The gap-fill layers 130 may include a material having etch selectivity with respect to the second sacrificial layer SL2. In an example embodiment, the gap-fill layers 130 may include polysilicon, metal, conductive metal nitride, or a combination thereof. For example, the gap-fill layers 130 may include polysilicon.

Referring to FIGS. 20A to 20C, an opening OP may be formed between the gap-fill layers 130 by etching an upper portion of the first preliminary gate structures 140p. For example, the second sacrificial layer SL2, the dielectric material layer 122p and the preliminary capping layer 126p may be partially etched by an etch-back process such that the openings OP may be formed. The openings OP may expose side surfaces of the gap-fill layers 130. In FIG. 20B, upper surfaces of the dielectric material layer 122p and the preliminary capping layer 126p after etching may be coplanar with an upper surface of the interlayer insulating layer 19, but example embodiments are not limited thereto. In an example embodiment, upper surfaces of the dielectric material layer 122p and the preliminary capping layer 126p after etching may be disposed at a level higher than a level of the upper surface of the interlayer insulating layer 19.

Referring to FIGS. 21A to 21C, a second mask layer M2 filling the opening OP may be formed. For example, the second mask layers M2 may be disposed on the first preliminary gate structures 120p. The second mask layers M2 may extend along the first preliminary gate structures 120p in the Y-direction and may be spaced apart from each other in the X-direction. A horizontal width of the second mask layers M2 in the X-direction may be greater than a horizontal width in the X-direction of the first preliminary gate structures 120p.

The second mask layer M2 may include a material having etch selectivity with respect to the interlayer insulating layer 19 and the preliminary active pattern 140p. In an example embodiment, the second mask layer M2 may include polysilicon, metal, conductive metal nitride, or a combination thereof.

Referring to FIGS. 22A to 22C, the gap-fill layers 130 may be removed, and the second sacrificial layer SL2 may be exposed. Because the second sacrificial layer SL2 includes a material having etch selectivity with respect to the gap-fill layers 130, the second sacrificial layer SL2 may not be etched, and the gap-fill layers 130 may be selectively removed.

Referring to FIGS. 23A to 23C, the preliminary active patterns 140p may be etched using the second mask layer M2 as an etch mask, thereby forming the active patterns 140. For example, preliminary active patterns 140p extending in the X-direction may be etched such that active patterns 140 spaced apart from each other in the X-direction may be formed. As illustrated in FIG. 1A, in the plan diagram, the active patterns 140 may have a bar shape extending in the Y-direction and may be spaced apart from each other in the X-direction and the Y-direction. The active patterns 140, the interlayer insulating layers 19 and the intermediate layer 12 may define gate trenches T3. For example, the gate trenches T3 may extend between the first preliminary gate structures 120p in the Y-direction and may be spaced apart from each other in the X-direction. The gate trenches T3 may expose side surfaces of the active patterns 140 and the interlayer insulating layers 19 and an upper surface of the intermediate layer 12.

The interlayer insulating layer 19 may also be etched by the etching process. Because a horizontal width of the second mask layers M2 in the X-direction is greater than a horizontal width of the first preliminary gate structures 120p in the X-direction, the dielectric material layer 122p of the preliminary gate structures 120p may not be exposed. For example, the etched interlayer insulating layer 19 may extend in the Y-direction along the dielectric material layer 122p. A portion of an upper surface of the intermediate layer 12 may be covered by the interlayer insulating layer 19 and may not be exposed, but example embodiments are not limited thereto.

In an example embodiment, a doping process may be performed on the active patterns 140 exposed by the gate trenches T3. For example, by performing a doping process such as a gas phase doping (GPD) process or a plasma doping (PLAD) process, the active patterns 140 may be doped with N-type impurities or P-type.

Referring to FIGS. 24A to 24C, the second mask layer M2 may be removed. The second mask layer M2 may include a material having etch selectivity with respect to the interlayer insulating layer 19 and the preliminary active pattern 140p, such that the interlayer insulating layer 19 and the active pattern 140 may not be etched.

Referring to FIGS. 25A to 25C, second preliminary gate structures 150p filling gate trenches T3 may be formed between the active patterns 140. The forming the second preliminary gate structures 150p may include filling the gate trenches T3 with a dielectric material, a conductive material, and an insulating material.

A dielectric material layer 152p may be deposited on an internal wall of the gate trenches T3, a conductive material layer may be formed on the dielectric material layer 152p, and the conductive material layer may be etched back, thereby forming gate electrode layers 154p. The dielectric material layer 152p may cover upper surfaces of the first preliminary gate structures 120p, a side surface of the active pattern 140, and an upper surface of the intermediate layer 12. The gate electrode layers 154p may be disposed on both sides of the first preliminary gate structures 120p, and may extend in the Y-direction. Gap-fill insulating layers 156p may be formed on the gate electrode layers 154p to completely fill the gate trenches T3. The gap-fill insulating layers 156p may be disposed on the gate electrode layers 154p, and may extend in the Y-direction.

The dielectric material layer 152p, the gate electrode layer 154p, and the gap-fill insulating layer 156p may form the second preliminary gate structure 150p. An upper surface of the second preliminary gate structure 150p may be parallel with the second sacrificial layer SL2. The second preliminary gate structures 150p may be alternately disposed in the X-direction with the first preliminary gate structures 120p, and may extend in the Y-direction.

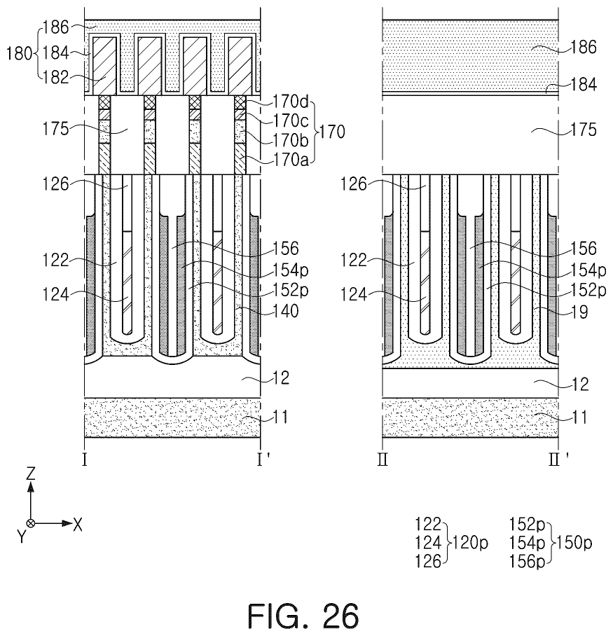

Referring to FIG. 26, the first buffer layer 15 and the second sacrificial layer SL2 may be removed, and by etching upper portions of the dielectric material layer 122p and the preliminary capping layer 126p, the back gate dielectric layer 122 and the upper capping layer 126 may be formed. The back gate dielectric layer 122, the back gate electrode 124, and the upper capping layer 126 may form a back gate structure 120. An upper surface of the back gate structure 120 may be coplanar with an upper surface of the active pattern 140 and an upper surface of the second preliminary gate structure 150p.

A contact pattern 170 and a data storage structure 180 may be formed on one end of the active patterns 140. The contact pattern 170 may include a first contact pattern 170a, a second contact pattern 170b, a third contact pattern 170c, and a fourth contact pattern 170d stacked in order. The contact pattern 170 may be electrically connected to the active pattern 140.

In an example embodiment, conductive material layers may be deposited on the first preliminary gate structures 120p, the second preliminary gate structures 150p and the active patterns 140, and insulating layers penetrating the conductive material layers may be formed, thereby forming the contact patterns 170 and the insulating structures 175. The insulating structures 175 may electrically insulate the contact patterns 170 from each other. In an example embodiment, at least one conductive material layer of the conductive material layers may include doped polysilicon. By a heating process, impurities included in the doped polysilicon may diffuse into the active patterns 140, and second source/drain regions may be formed on the one ends of the active patterns 140.

A data storage structure 180 including first electrodes 182, a dielectric layer 184 and a second electrode 186 may be formed on the contact patterns 170. The first electrodes 182 may be in contact with the fourth contact patterns 170d of the contact patterns 170.

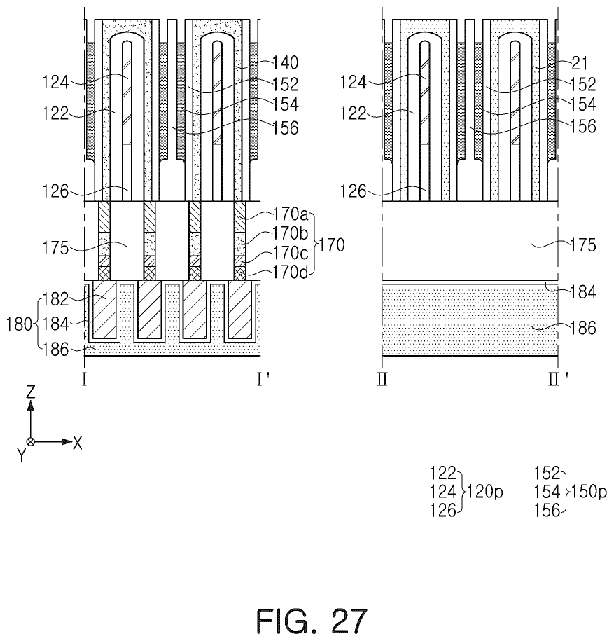

Referring to FIG. 27, the resulting structure in FIG. 23 may be flipped such that the data storage structure 180 faces downward, and the lower substrate 11 and the intermediate layer 12 may be removed. The intermediate layer 12 may be removed such that dielectric material layers 152p of the second preliminary gate structures 150p may be exposed. The exposed dielectric material layers 152p may be etched such that the gate dielectric layers 152 may be formed. Thereafter, the gate electrode layers 154p may be etched-back such that the wordlines 154 may be formed. When the wordlines 154 is formed, the gap-fill insulating layer 156p may be partially etched such that the gap-fill insulating layer 156 may be formed.

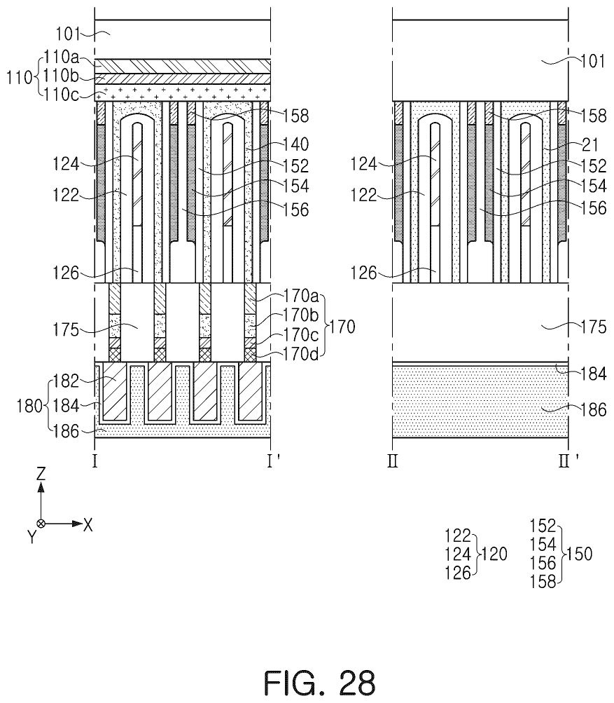

Referring to FIG. 28, gate capping layers 158 may be formed by filling an insulating material on the wordlines 154. The gate dielectric layer 152, the wordline 154, the gap-fill insulating layer 156, and the gate capping layer 158 may form a wordline structure 150.

A lower insulating layer 101 and bitline structures 110 may be formed on the other end of the active patterns 140, such that a semiconductor device 100 may be manufactured. The bitline structures 110 may include a third conductive pattern 110c, a second conductive pattern 110b, and a first conductive pattern 110a stacked in order on the active patterns 140.

In an example embodiment, the third conductive pattern 110c in contact with the active patterns 140 may include doped polysilicon. By the heating process, impurities included in the doped polysilicon may diffuse into the active patterns 140, and first source/drain regions may be formed on the other ends of the active patterns 140.

In an example embodiment, a peripheral circuit structure including peripheral circuit devices electrically connected to at least one of the bitline structures 110 may be disposed on the lower insulating layer 101. In an example embodiment, the peripheral circuit structure may be disposed on the data storage structure 180 after the data storage structure 180 is formed.

In an example embodiment, a cleaning process may be further performed before the bitline structure 110 is formed. The cleaning process may remove an oxide film formed on the active patterns 140. The cleaning process may partially etch the gate dielectric layer 152, and side surfaces of the active patterns 140 may be exposed. The side surfaces of the exposed active patterns 140 may be in contact with the bitline structure 110.

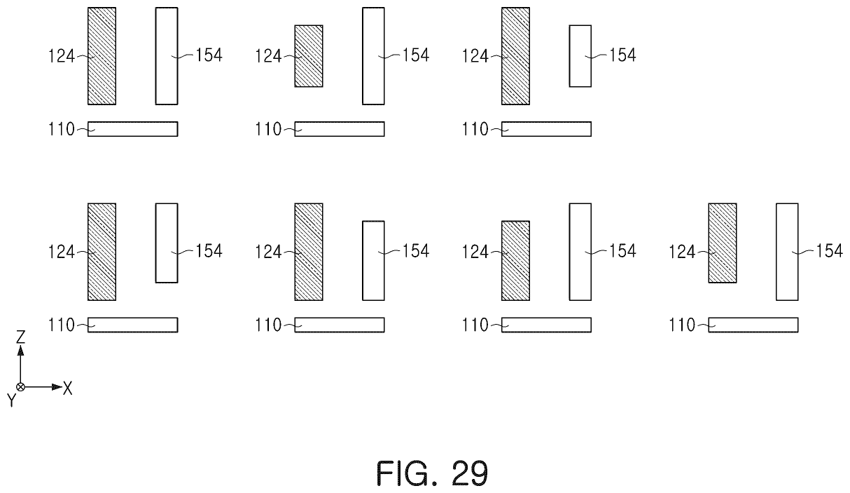

FIG. 29 is a cross-sectional diagram illustrating a layout structure of a back gate electrode and a wordline included in a semiconductor device according to an example embodiment.

Referring to FIG. 29, an upper surface of the back gate electrode 124 and an upper surface of the wordline 154 may be disposed at the same level or different levels. A lower surface of the back gate electrode 124 and a lower surface of the wordline 154 may be disposed at the same level or different levels. Here, the lower surface of the back gate electrode 124 and the lower surface of the wordline 154 may refer to a surface of the back gate electrode 124 and a surface of the wordline 154 opposing the bitline structure 110, respectively. An upper surface of the back gate electrode 124 and an upper surface of the wordline 154 may be surfaces opposing the lower surface of the back gate electrode 124 and the lower surface of the wordline 154, respectively. A vertical length in the Z-direction of the back gate electrode 124 and a vertical length in the Z-direction of the wordline 154 may be the same or different.

According to the aforementioned example embodiments, because the lower surface of the active pattern has an area greater than the upper surface of the active pattern, resistance between the active pattern and the bitline structure may be reduced.

While some example embodiments have been illustrated and described above, it will be configured as apparent to those skilled in the art that modifications and variations could be made without departing from the scope of the present disclosure as defined by the appended claims.

What is claimed is:

1. A semiconductor device, comprising:
a bitline structure;
a first gate structure extending in a first horizontal direction on the bitline structure, the first gate structure including a first gate electrode;
a second gate structure extending in the first horizontal direction on the bitline structure, the second gate structure including a second gate electrode;
an active pattern including a portion being between the first gate structure and the second gate structure; and
a contact pattern on the active pattern,
wherein the active pattern is in contact with an upper surface of the bitline structure and in contact with side surfaces and a lower surface of the first gate structure.

2. The semiconductor device of claim 1, wherein
the active pattern includes a first vertical pattern, a second vertical pattern, and a horizontal pattern, the first vertical pattern and the second vertical pattern extending in a vertical direction, the horizontal pattern extending in a horizontal direction,
the first vertical pattern and the second vertical pattern are apart from each other in a second horizontal direction intersecting the first horizontal direction,
the first gate structure is between the first vertical pattern and the second vertical pattern, and
the horizontal pattern is between the first vertical pattern and the second vertical pattern.

3. The semiconductor device of claim 2, wherein the horizontal pattern is in contact with the upper surface of the bitline structure and the lower surface of the first gate structure.

4. The semiconductor device of claim 2, wherein a sum of areas of a lower surface of the first vertical pattern, a lower surface of the second vertical pattern and a lower surface of the horizontal pattern is greater than an area of an upper surface of the first vertical pattern.

5. The semiconductor device of claim 2, wherein an upper surface of the first vertical pattern and an upper surface of the second vertical pattern are coplanar with an upper surface of the first gate structure.

6. The semiconductor device of claim 1, further comprising:
a lower insulating layer below the first gate structure and the second gate structure, a portion of the lower insulating layer being under the first gate structure and coplanar with the upper surface of the bitline structure; and
an insulating pattern on the lower insulating layer, and the insulating pattern extending in the first horizontal direction.

7. The semiconductor device of claim 6, wherein the insulating pattern is in contact with an upper surface of the lower insulating layer and in contact with the side surfaces and the lower surface of the first gate structure.

8. The semiconductor device of claim 7, wherein
the insulating pattern includes a first vertical insulating pattern, a second vertical insulating pattern and a horizontal insulating pattern, the first vertical insulating pattern and the second vertical insulating pattern extending in a vertical direction, the horizontal insulating pattern extending in a horizontal direction,
the first vertical insulating pattern and the second vertical insulating pattern are apart from each other in a second horizontal direction intersecting the first horizontal direction,
the first gate structure is between the first vertical insulating pattern and the second vertical insulating pattern, and
the horizontal insulating pattern is between the first vertical insulating pattern and the second vertical insulating pattern.

9. The semiconductor device of claim 6, wherein a maximum horizontal width in a second horizontal direction intersecting the first horizontal direction of the insulating pattern is less than or same as a horizontal width in the second horizontal direction of the active pattern.

10. The semiconductor device of claim 6, wherein
the first gate structure includes a first portion in contact with the active pattern and a second portion in contact with the insulating pattern, and
the first portion is at a level different from a level of the second portion.

11. The semiconductor device of claim 1, wherein
the first gate structure further includes a first gate dielectric layer in contact with a side surface and a lower surface of the first gate electrode, and
the first gate dielectric layer is apart from the bitline structure in a vertical direction.

12. The semiconductor device of claim 11, wherein the first gate structure further includes a spacer layer, the spacer layer being below the first gate dielectric layer and in contact with the active pattern.

13. The semiconductor device of claim 1, wherein
the second gate structure further includes a second gate dielectric layer in contact with a side surface of the second gate electrode, and
the second gate dielectric layer is in contact with the upper surface of the bitline structure.

14. A semiconductor device, comprising:
a bitline structure;
a first gate structure extending in a first horizontal direction on the bitline structure, the first gate structure including a first gate electrode;
second gate structures extending in the first horizontal direction on the bitline structure, each of the second gate structures including a second gate electrode, the second gate structures being apart from each other in a second horizontal direction intersecting the first horizontal direction with the first gate structure interposed therebetween;
an active pattern including a portion between the first gate structure and the second gate structures; and
a first contact pattern and a second contact pattern on the active pattern,
wherein the active pattern is electrically connected to the first contact pattern and the second contact pattern.

15. The semiconductor device of claim 14, wherein the active pattern is in contact with an upper surface of the bitline structure and in contact with side surfaces and a lower surface of the first gate structure.

16. The semiconductor device of claim 14, wherein a vertical length of the first gate structure is smaller than vertical lengths of the second gate structures.

17. The semiconductor device of claim 14, wherein a horizontal width in the second horizontal direction of the active pattern is same as a distance between the second gate structures.

18. The semiconductor device of claim 14, wherein an area of a lower surface of the active pattern is greater than an area of an upper surface of the active pattern.

19. The semiconductor device of claim 14, wherein, in a cross-sectional diagram, the active pattern has a U-shape.

20. A semiconductor device, comprising:
a bitline structure;
a first gate structure extending in a first horizontal direction on the bitline structure, the first gate structure including a first gate electrode and a first gate dielectric layer, the first gate dielectric layer being in contact with a side surface and a lower surface of the first gate electrode;
a second gate structure extending in the first horizontal direction on the bitline structure, the second gate structure including a second gate electrode and a second gate dielectric layer, the second gate dielectric layer being in contact with a side surface of the second gate electrode;
an active pattern including a portion being between the first gate structure and the second gate structure;
a contact pattern on the active pattern; and
a data storage structure on the contact pattern,
wherein the active pattern is in contact with an upper surface of the bitline structure, and in contact with side surfaces and a lower surface of the first gate structure, and
wherein a lower end of the first gate dielectric layer is apart from the bitline structure in a vertical direction and is at a level higher than a level of a lower surface of the second gate dielectric layer.
